(19) United States
(12) Patent Application Publication
(10) Pub. No.: US 2002/0199142 A1
(43) Pub. Date: Dec. 26, 2002

(54) Semiconductor programming and testing method and apparatus

(76) Inventor: Moshe Gefen, Modi-in (IL)

Correspondence Address: MORGAN & FINNEGAN, L.L.P., 345 Park Avenue, New York, NY, 10154-0053, US

(21) Appl. No.: 10/180,574

(22) Filed: Jun. 26, 2002

Related U.S. Application Data
(60) Provisional application No. 60/300,987, filed on Jun. 26, 2001.

(51) Int. Cl. G01R 31/28

(52) U.S. Cl. 714/724

(57) ABSTRACT

Systems and methods relating to semiconductor testing and programming, including semiconductor-chip testing apparatuses, semiconductor-chip programming apparatuses, semiconductor testing integrated-circuit chips (“TIC's”), employable in testing and/or programming semiconductor integrated circuits. Such TICS may be full testers, capable of performing tests such as AC, DC, functional, and mixed signal (analog) tests, and/or may be capable of performing design verification and/or characterization.

### FIELD OF INVENTION

This invention relates to systems and methods for semiconductor testing and programming.

### BACKGROUND INFORMATION

The production of a semiconductor is a complex process that requires increasingly sophisticated engineering and manufacturing expertise, which takes the semiconductor device through more than 500 steps. As a complex, multi-step process, defects or weaknesses may occur at any process step, and may result in the failure of an IC, immediately or at any time during the operating life of an IC (sometimes after several months of normal use). Therefore, semiconductor manufacturers rely on testing and reliability screening—conducted at two different stages—to detect failures that occur during the manufacturing process.

The production process can be broadly divided into three main stages:

Wafer fabrication, including wafer probing;

Assembly of bare semiconductors, or die, into finished semiconductors (referred to as “assembly” or “packaging”); and

Final testing of assembled semiconductors.

Illustrated in FIG. 1 is an exemplary IC (integrated circuit) manufacturing process, the steps of which will now be explained in detail.

Step 103—Wafer Fabrication. After wafer preparation (step 101), wafer fabrication takes place. The wafer fabrication process begins with the generation of a mask that defines the circuit patterns for the transistors and interconnect layers that will be formed on the raw silicon wafer. The transistors and other circuit elements are formed by repeating a series of process steps where photosensitive material is deposited onto the wafer; the material is exposed to light through the mask in a photolithography process; and finally the unwanted material is removed through an etching process, leaving only the desired circuit pattern on the wafer.

Step 105—Wafer Probing. The first set of tests is typically performed after the wafer fabrication and before the processed semiconductor wafer is cut into individual die, in order to avoid the cost of packaging defective die into their plastic or ceramic packages. This testing step has several names, including “front-end testing”, “wafer testing” or “wafer probing”. In a front-end testing, a piece of equipment known as a wafer prober automatically positions the wafer under a “test head”, which is connected electronically to a test system. In this process, each individual die on the wafer is electrically tested in order to identify the operable semiconductors for assembly. Wafer probing involves inspection of the processed wafer for defects to ensure it meets customer acceptance criteria. Wafer probe test typically occurs in a clean room where potential contaminants must be continually removed and temperatures kept constant. These special maintenance requirements make clean rooms expensive to operate. Dies on an accepted wafer are then individually inspected visually and with scanners before assembly and final testing.

Steps 107 and 109—Assembly and Packaging. Assembly protects the semiconductor, facilitates its integration into electronic systems and enables the dissipation of heat. In the assembly process, the wafer is diced into individual die that are then attached to a substrate with an epoxy adhesive. Leads on the substrate typically are then connected by extremely fine gold wires to the input/output terminals on the die through the use of automated equipment known as “wire bonders.” Each die is then encapsulated in a molding compound, thus forming the package.

Step 111—Final Testing. The packaged IC also requires testing, a stage called “back-end testing” or “final testing”. The purpose of this testing is to determine whether or not the packaged device meets its design and performance specifications. Various aspects of this stage are illustrated in FIG. 2.

As a first step in final testing, after the die are packaged and before they undergo reliability screening, a short test is typically performed in order to detect packaging defects. Then, primarily applicable to most leading-edge microprocessors, microcontrollers, digital signal processors, and memory ICs, such devices undergo an extensive reliability screening and stress testing procedure known as “burn-in.” The burn-in process screens for early failures by operating the IC at elevated voltages and temperatures, usually at 125 degrees Celsius (257 degrees Fahrenheit), for periods typically ranging from 12 to 48 hours. In this process thousands of integrated circuit chips are placed on a burn-in board that is similar to a computer add-on card, but usually much larger. The burn-in board is a printed circuit board with receptacles for the integrated circuit chips. The burn-in board also includes printed circuit connections between pins of the integrated circuit chips and connectors of the burn-in board. Shown in FIG. 2 is burn-in system 201.

After burn-in, the ICs undergo a final test process using automatic test equipment 203 (“testers” or “ATE”). It is a highly complex process that uses sophisticated testing equipment and customized software programs to electrically test a number of attributes of assembled semiconductors, including functionality; speed; predicted endurance; power consumption; and electrical characteristics (AC and DC parametric testing). In the final testing, packaged ICs are placed into a machine called a handler, which then plugs the packaged ICs into an environmentally-controlled test head, which includes a test socket.

Step 113—IC Programming. Typically, final testing is the last step in the production of ICs, after which the ICs are shipped as directed by the customer for integration into the end-products. However, a wide range of memory ICs is also going through a programming process, whereby the packaged IC is loaded with relevant software (for example, each handheld device is loaded with the operating system software required for its operation). Programming is typically executed by programming service companies, IC distributors or by the OEM manufacturer, utilizing automatic- or manual-programming systems.

The testing process of integrated circuit (semiconductor device, chips, ICs) during the production process is conducted by automatic test equipment (“ATE” or “tester”) that executes a test pattern that is made up of test vectors.

Each test vector may contain:

a. Information about the test signals that should be applied to the device under test (“DUT”)

b. Timing instructions when to drive or receive signals from a properly functioning DUT during one cycle of the tester's operation.

Purely digital devices, such as memory and logic devices, are usually tested with automatic test equipment that drive and receive digital signals. The major components of a traditional memory/logic tester are:

A Mainframe—controls the test, generates test signals, and analyzes responses to identify errors during a test.

A Test Head—connects the main frame to the DUT and routes the various test signals to the DUT. The test head also contains electronic circuitry which must be positioned close to the DUT to provide good signal integrity and reduce noise; however, the mainframe itself is connected to the test head through expensive cables to increase signal integrity and reduce noise.

Control Electronics—located inside the tester's main frame, and operative to control the tester. The control electronics comprise a high-speed computer, which includes a programmable memory so that the tester can perform numerous tests on a variety of semiconductor devices. The control electronics also comprise a central algorithmic pattern generator (APG), which is an extremely complex and costly device, consisting of several PC boards or at least customized IC's (ASICs).

The control electronics are connected over one or more buses to the following tester subsystems:

A subsystem that processes AC signals.

A subsystem that processes DC signals. The DC subsystem comprises DC sources and receivers. These devices can produce or measure DC biased conditions.

A subsystem that processes digital signals. The digital subsystem generates and receives digital signals. It is made up of digital drivers and receivers.

In addition, semiconductor devices which process analog as well as digital signals must be tested with testers which can produce and receive analog and digital signals. These testers are called mixed signal testers.

A mixed signal tester includes subsystems that process RF (radio frequency) signals (loosely defined as those signals having frequencies in the range of about 10 MHz up to about 6 GHz) through a plurality of RF sources and receivers, each of which measures the parameters of a received signal over a range of frequencies.

The RF, DC, AC, and digital subsystems are all connected to the test head. In many instances, the test head contains distributed electronics portions of the sources or receivers in the RF, AC, DC and digital subsystems that must be positioned near DUT for greater accuracy or other reasons.

Different concepts have been used to test integrated circuits containing logic circuitry and integrated circuits containing memories. The first group of devices has often been referred to as “LSI testers,” whereas the latter group has been referred to as “memory testers.”

Another approach to classify integrated circuit testers is by their internal structure. Two general concepts are known in the prior art, namely the “shared resource” approach and the “distributed resource” or “per pin resource” approach.

FIG. 3 depicts an exemplary structure of a tester based on the “per-pin resource” approach. Shown in Fig. are timing circuit 301, fast memory element 303, failure analysis element 305, signal driver 307, signal comparator 309, calibration circuit 311, fast current measurement element 313, and parameter measurement unit (PMU) 315.

IC testers employing the per-pin-resource approach comprise logic circuitry that is dedicated to a specific terminal (pin) of the DUT. In other words, the same kind of logic circuitry exists multiple times in an IC tester, once for every pin of the DUT. If the IC tester is set up to test DUT with a given maximum n of pins, this means that the pin circuitry has to be provided n times; n can approximate several hundred or even exceed some thousand, in view of state-of-the-art semiconductor chips and the related packaging technology.

The pin circuitry (pin channel or terminal channel) commonly comprises driver circuits (307) for the assigned pin, and mostly also formatter and comparator circuits (309). The latter are circuits which combine data and timing information (formatter), or test a signal received from the assigned terminal for its timing and correct logic state (comparator).

The “per pin resource” approach provides control circuitry, or at least the speed-critical part thereof, for every pin channel. This approach may overcome speed restrictions of the Shared Resource approach; however, it may be very expensive as the control circuitry has to be provided n times. Sometimes even the speed of a “per pin” resource does not fit the requirements of a particular application.

FIG. 4 illustrates an exemplary tester head applicable to the per-pin-resource approach. Shown in FIG. 4 are loading board 401, channels board 403, and test head cover 405.

In contrast, the “Shared Resource” approach is based on sharing the control circuitry, or part thereof, among multiple pins. For example, the control circuitry may be provided only once, and communicate with the pin channels (terminal channels) via a common bus. This eliminates the need to replicate the control circuit for every pin of the DUT, and is therefore less expensive. However, it can operate only at limited speed, and therefore does not fit the need to test memories at acceptable speed, particularly as the capacity of memories is increasing, and as there is a need to increase the rate of testing.

In the case of conventional memory testers, a central algorithmic pattern generator (APG) has been provided (as a shared resource for all pin channels). The APG is an extremely complex and costly device, consisting of several PC boards or at least customized IC's (ASICs). Typically, it provides a first generator for the x addresses of the DUT, a second generator for the y addresses, a third data generator, and a controller. Their operation can be illustrated by the creation of a zero pattern in the DUT. In this case, the data generator would generate a permanent “0”. The X address generator would run from “0” to a predefined end address, whereas the y address generator would keep its value. As soon as the x address generator would reach its end address, it would be reset to “0”; the y address generator would be increased by one, and the x address generator would again run from “0” to its end address. The whole process would go on until all cells of the memory under test contained a “0”.

The controller of such an APG includes a programmable memory which contains the sequences to be generated, or a program which generates such sequences.

It is understood that, due to the interconnection of the control signals and the propagation delay times caused thereby, an APG of conventional design can operate only at limited speed. This applies even if very fast and expensive APGs are used, as has been common practice.

Thus, such memory testers using the “shared resource” concept do not fit the need to test memories at acceptable speed. This applies particularly as the capacity of memories is increasing, and as there is a need to increase the rate of testing.

Another problem arises as more and more integrated circuits contain logic circuitry, as well as memories, on the same chip. This applies particularly to customized IC's such as ASICs. It would hardly be possible to test such devices with IC testers designated specifically to memory or logic test in a given time frame. Even a combined tester incorporating memory and logic test circuitry would not fit those needs: such a tester would have to provide different circuitry for pins designated as logic pins as compared to pins designated as memory pins.

Another tester structure, similar to that described in U.S. Pat. No. 5,497,079, is schematically depicted in FIG. 5. Shown in FIG. 5 are testing IC's 501, each having its own SRAM (static random access memory) 503 and pattern generator (505). Automatic test equipment (“ATE” or “tester”) may execute a test pattern that is made up of test vectors.

To fully test a DUT, it is often necessary to run several tests programs. First, the tester makes a first measurement by specifying the settings for the DUT. After the measurement is made and passed back to control electronics, the tester takes the next measurement, until all the required measurements are taken.

Operation of the tester is controlled by a host computer that generates, for each test cycle, a test pattern (signals) for each channel. The test pattern applied to or received from the DUT is processed in a separate “channel” of the tester, under precise timing parameters, which specify precisely when a signal should occur. For this purpose, two pieces of information are usually required:

First, the length of one cycle, or period, of the test (generally the same for all channels);

Second, the length of time after the start of the cycle is specified for the signal (this time, or delay, may be different in each channel).

In addition, the typical test channel also includes a test pattern memory into which the test patterns are loaded prior to test execution and a sequencer which generates a sequence of addresses for reading the test patterns from the test pattern memory and supplying the test patterns to the pin electronics circuit in the proper order. See FIG. 5.

Many memory IC's go through a programming process whereby packaged ICs are loaded with relevant software. For example, IC's for a handheld device may be loaded with the operating system software required for the handheld's operation. Programming is typically executed by a programming system that could be operated manually or automatically.

As noted in U.S. Pat. No. 5,996,004, in the semiconductor industry, a considerable number of electronic devices are provided by vendors in programmable form with blank memories or unspecified connections between arrays of logic circuits. Users can then custom configure or program the electronic devices to perform their intended functions by programming them, transferring or “burning in” a sequence of operating codes into the memory, or by specifying a particular arrangement of gating logic connections.

Special purpose programming machines, known as device programmers, have been developed to allow designers and engineers to rapidly transfer these codes, gating logic arrangements and the like into the programmable devices. The initial type of device programmer was a stand alone or single device programmer, allowing an operator to insert and program individual devices according to end user requirements. The programming pattern for the device was transferred into the device from a device programming computer or logic circuit.

The more recent type of device programmers developed were known as gang programmers. These were intended for large production runs of the same type or model of programmable device. An array of device programming sites like the single site station ones operated in parallel in a common programming sequence according to production programming codes from a single central computer. A set or production run group of devices would be loaded into the array of programming sites. When the sites were loaded, the array of devices was then programmed in a common, ganged sequence, each device starting and completing the programming sequence in common with each of the other devices.

There were, however, several undesirable features to gang programming. One of these was time inefficiency. When the programming machine was being loaded with blank devices by the operator, none of the programming sites was operating due to the required common starting and operating sequence. Further, once the programming machine was loaded and started into the programming run, the machine operator was idle until the gang programming sequence was completed.

Also, it was difficult to monitor the status or progress of the programming. If a machine operator was distracted or interrupted when loading or unloading an array of programming sites, it was very difficult without repeating the programming cycle to determine whether the devices were either beginning blank ones or completed programmed devices because the gang programmer or conventional programmer's status indicator continues to indicate that the last device programmed in each site was successfully programmed even after the successfully programmed device was removed and a blank device was inserted into the programming site. Additionally, a number of types of semiconductor devices, due to increasing productivity requirements, might have slightly, but not inconsequentially, different operating parameters or characteristics.

An example would be the programming voltage level. These variations might even occur among devices in the same production run from the semiconductor manufacturer. Nevertheless, gang programming might be attempted of a number of such devices based on an assumed existence of common parameters. If there were in fact variations in the operating parameters, even if minor ones, gang programming could result in flawed or defective production of programmed devices because the gang programmer applies similar waveform voltages and pulse widths to each of the devices being programmed in the set.

One disadvantage of gang programmers was software complexity. The software had to be written such that it can apply waveforms to all devices simultaneously and verify that each programmed device verifies correctly. As programming algorithms increased in complexity to handle more complex devices, the difficulty in writing such software increased disproportionately.

The only available option for many users was to operate a number of conventional single-site programmers side by side. Doing so allowed increased operator efficiency, but also some disadvantages. First, each site was a separate and complete programmer, thus duplicating the user interface and the algorithm storage requirements, thereby increasing cost and complexity. Second, each system was configured by the user independently, thus taking time and allowing simple operator error to cause quality problems. Third, each system's status was reported separately, so status of the total operation was indeterminable except by manual methods. Finally, if a new algorithm was required to program a particular type of device, each station was required to be loaded with the new algorithm.

U.S. Pat. No. 5,996,004 relates to an apparatus and method for programming a plurality of electronic devices. A control computer and a suitable number of programming sites, each of which includes its own computer, are connected together. One of the programming sites serves as a master site during initial set up for a programming run of a group of electronic devices. The control computer and the master site initially determine the programming sequence for the group of electronic devices. Thereafter, the control computer broadcasts the determined operating sequence to all the programming sites. The sites then operate independently of one another, each being adapted to receive and transfer code to a device without regard to the operating status of the other sites. The control computer polls the sites in a time sequence to provide monitoring and reporting functions at a common display. The programming sites according to U.S. Pat. No. 5,996,004 also include status detection circuitry to detect the status of transfer of the code into the device. For example, the status detectors at each site sense if the device is either ready to begin or is in progress for transfer of the operating code. After the transfer cycle is complete, the status detector senses and causes an indicator to indicate whether a particular device has satisfactorily completed receipt of the code or whether the code transfer was faulty. If the device is removed, status changes again. For example, after a successfully programmed device is removed, the pass indicator is turned off thereby eliminating the possibility that a blank device will be interpreted as programmed.

### SUMMARY OF INVENTION

According to embodiments of the present invention, there are provided systems and methods relating to semiconductor testing and programming. Disclosed, for example, are semiconductor-chip testing apparatuses, semiconductor-chip programming apparatuses, semiconductor testing integrated-circuit chips (“TICs”), employable in testing and/or programming semiconductor integrated circuits. Such testing methods and apparatuses may be employed at any point in the manufacturing process, such as at the wafer level (e.g., by coupling such methods and apparatuses with a probe card), and at the packaged die level before, during or after burn-in. According to various embodiments of the present invention, a TIC may be a full tester, capable of performing tests such as AC, DC, functional, and mixed signal (digital and analog) tests for various types of devices, such as digital logic, memory, mixed signal, RF and analog devices, and system on a chip (SOC). Further, one TIC (or more than one TIC) may be used to concurrently and/or simultaneously test and/or program not only identical devices, but also non-identical devices (such as NAND Flash devices) as well as different types of devices (e.g., different architectures, different packages, different pin counts, different testing and/or operating frequencies, different time sets, and/or different functions, etc.). It is further noted that embodiments provide TICs capable of performing design verification and/or characterization.

In accordance with an aspect of the present invention a system for testing and/or programming at least one integrated circuit, comprises a controller, a memory coupled to the controller, and a plurality of circuit modules (e.g, TICs). The memory is coupled to the controller by a first bus characterized by a first bandwidth, wherein said memory stores testing and/or programming information received from the controller via the first bus. The plurality of circuit modules are capable of coupling via a third bus to test and/or program at least one integrated circuit based on the testing and/or programming information stored in the memory, wherein the third bus is capable of operating at a third bandwidth greater than the first bandwidth of the first bus. In accordance with another aspect of the present invention, the third bus operates at a speed specified by the at least one integrated circuit.

In accordance with a further aspect of the invention, the plurality of circuit modules are configured to access the testing and/or programming information from the memory via a second bus that operates at a second bandwidth less than the third bandwidth.

In accordance with yet a further aspect of the invention, a testing and/or programming circuit module for testing and/or programming at least one integrated circuit comprises (i) a plurality of configurable pin channels each capable of being coupled to a respective node of the at least one integrated circuit, and (ii) a control circuit that is operative in coordinating the communication by each of the configurable pin channels with the respective nodes of testing and/or programming signals based on testing and/or programming information stored in a memory.

As a further aspect of the testing and/or programming circuit module, different configurable pin channels are configurable for concurrently testing and/or programming different ones of the at least one integrated circuit, thereby concurrently testing and/or programming a plurality of the at least one integrated circuit. Additionally, the at least one integrated circuit may include integrated circuits having different characteristics, such as, for example, distinct program code to be programmed by the testing and/or programming circuit module, or different time sets.

As yet a further feature of the testing and/or programming circuit module, each of the plurality of pin channels may be independently capable of at least DC, AC, and functional testing operations.

Such a testing and/or programming circuit module comprising the control circuit and the plurality of configurable channels may be implemented as a single integrated circuit, or alternatively as more than one integrated circuit or component. It may further include a test pattern generating circuit, a timing measuring circuit, and a formation circuit, as well as a failure analysis circuit.

In accordance with still a further aspect of the testing and/or programming circuit module, the control circuit may be operative to generate a representation of defective locations in at least one memory or programmable device to be programmed. The control circuit may further be operative in programming the at least one memory or programmable device based on the representation of defective locations in the at least one memory or programmable device.

An additional aspect of the present invention is that it provides a method for testing a plurality of integrated circuits, the method comprising conducting a burn-in operation on the plurality of integrated circuits located in a burn-in oven, and performing AC, DC, and functional testing on the plurality of integrated circuits while conducting the burn-in operation. Additionally, the method may further include programming the plurality of integrated circuits while located in the burn-in oven.

Yet still a another aspect of the present invention is that it also provides a method for programming a plurality of integrated circuits, the method comprising conducting a burn-in operation on the plurality of integrated circuits located in a burn-in oven, and programming the plurality of integrated circuits while located in the burn-in oven. The programming may be performed, for example, while conducting the burn-in operation, or after the burn-in operation but while the plurality of integrated circuits are still located in the burn-in oven.

### BRIEF DESCRIPTION OF DRAWINGS

Additional aspects, features, and advantages of the invention will be understood and will become more readily apparent when the invention is considered in the light of the following description made in conjunction with the accompanying drawings, wherein:

FIG. 1 illustrates an IC (integrated circuit) manufacturing process.

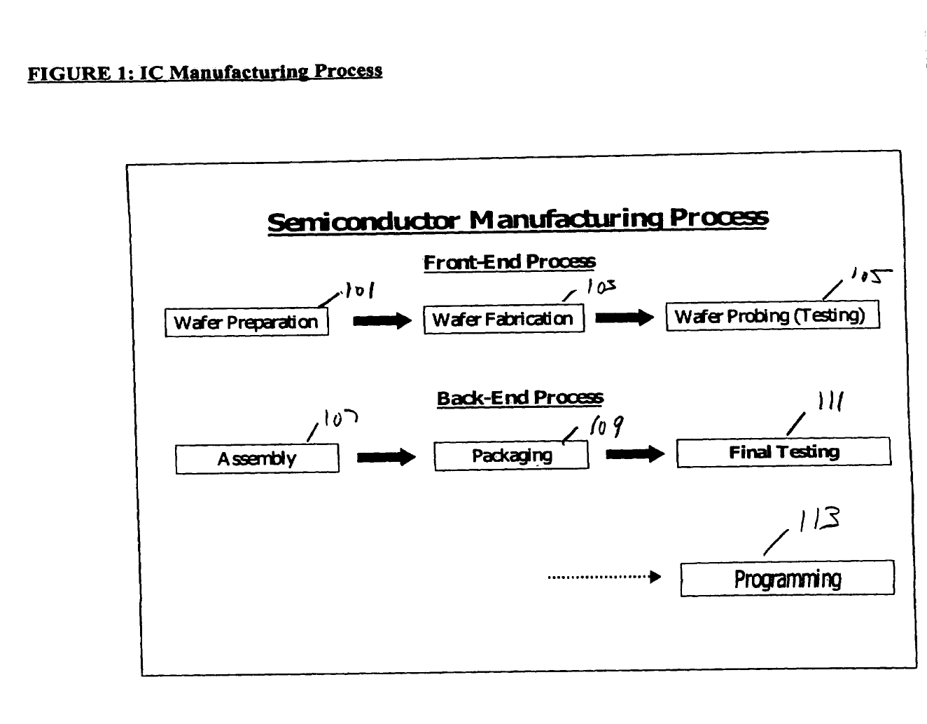

FIG. 2 illustrates a burn-in and final test process.

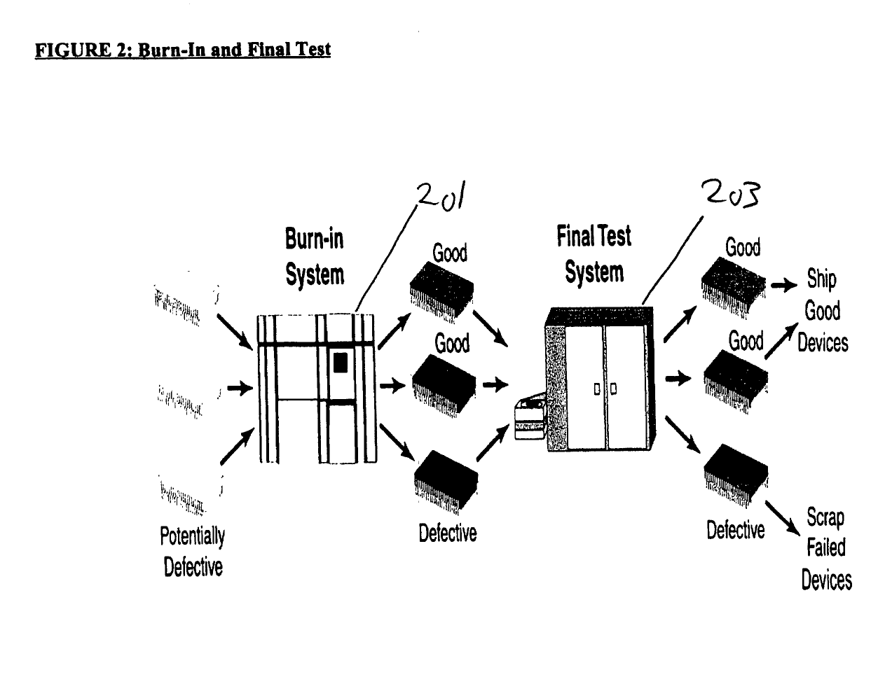

FIG. 3 shows a structure of a tester based on per-pin resource.

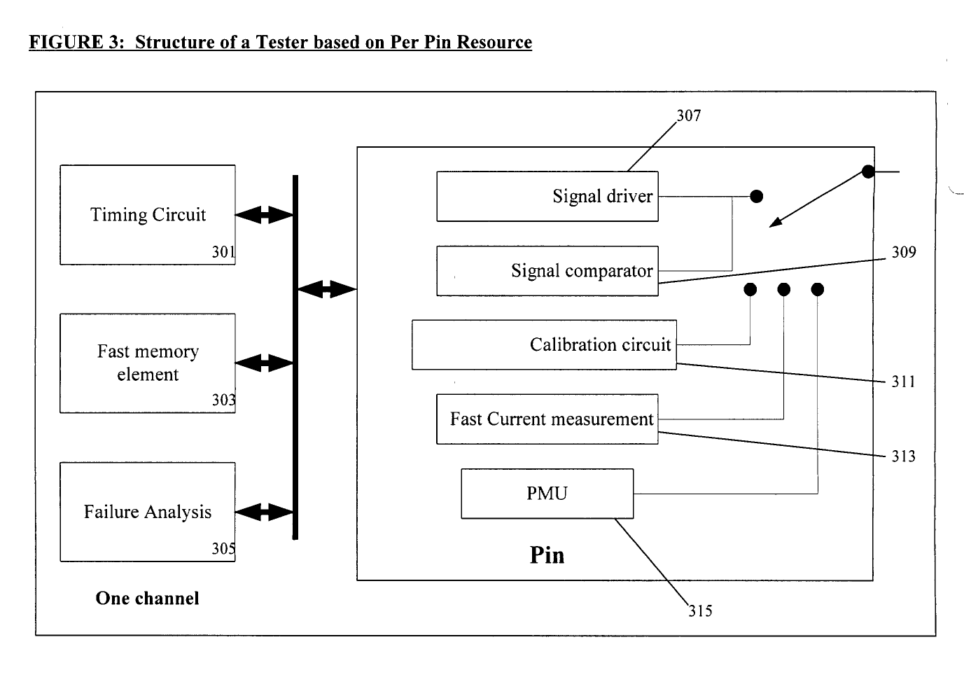

FIG. 4 shows a tester head structure.

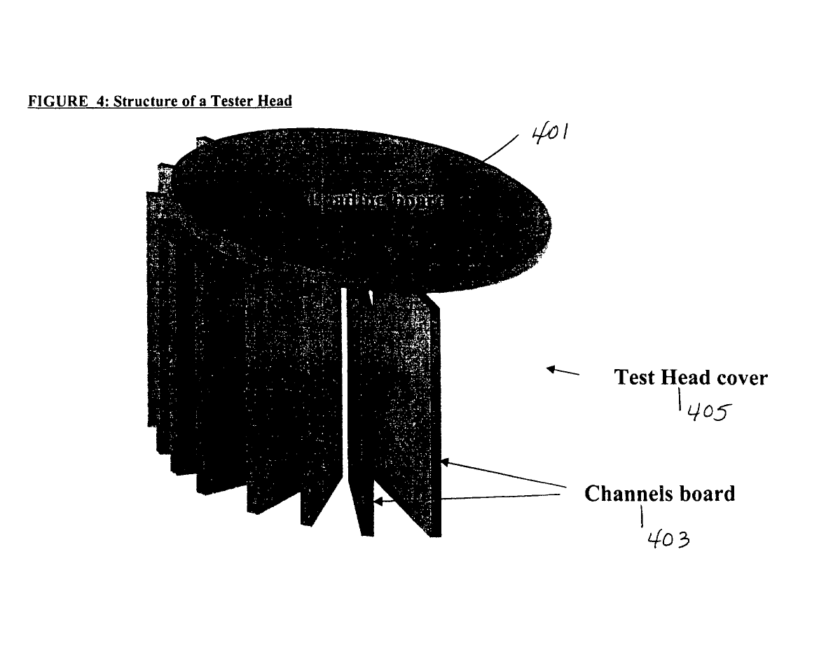

FIG. 5 shows a tester structure.

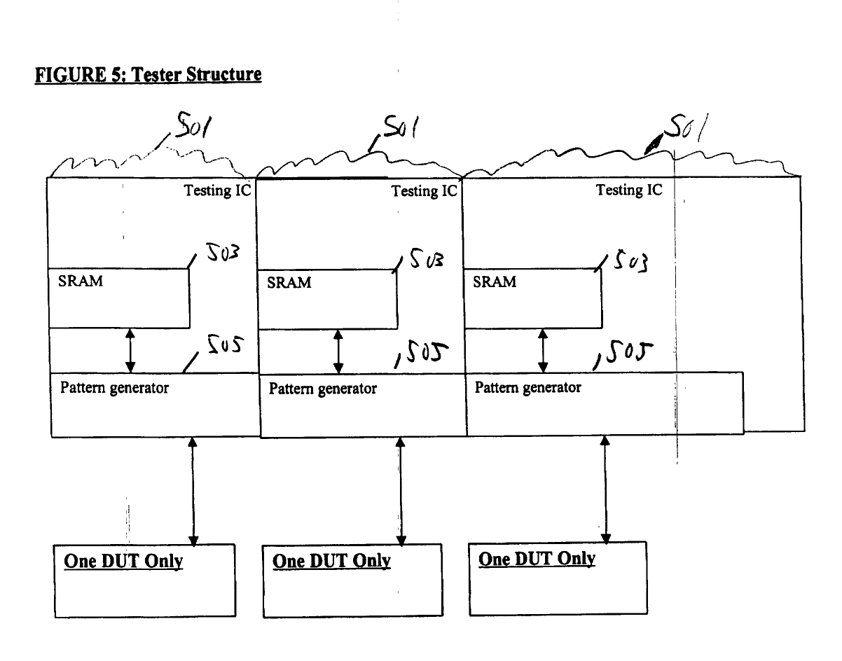

FIG. 6 shows the structure of an illustrative TIC (test IC) according to embodiments of the present invention.

FIG. 7 shows an implementation of ATE (automatic test equipment) according to embodiments of the present invention.

FIG. 8 shows the structure of a TIC I/O pin according to embodiments of the present invention.

FIG. 9A shows an architecture for full concatenation according to embodiments of the present invention.

FIG. 9B shows an independent approach architecture according to embodiments of the present invention.

FIG. 10 shows an implementation of ATE for final testing and/or programming according to embodiments of the present invention.

FIG. 11 shows a bottom view of a loading board employable in embodiments of the present invention.

FIG. 12 shows a top view of a loading board employable in embodiments of the present invention.

FIG. 13a shows a side view of a loading board employable in embodiments of the present invention.

FIG. 13b shows a side view of a loading board employable in various alternative embodiments of the present invention.

FIG. 14 is a flow diagram corresponding to a full-concatenation or limited-concatenation approach according to embodiments of the present invention.

FIG. 15 is a timing diagram corresponding to a full-concatenation or limited-concatenation approach according to embodiments of the present invention.

FIG. 16 shows a configuration corresponding to an integrated B/I (burn-in), final testing, and programming process according to embodiments of the present invention.

FIG. 17 shows an ATE system architecture according to embodiments of the present invention.

FIG. 18 shows an additional TIC implementation employable in applications including but not limited to IC programming.

FIG. 19 depicts a production flow for an assembly line.

FIG. 20a is a block diagram corresponding to a programming embodiment.

FIG. 20b is a signal/time graph corresponding to an illustrative time set.

### DETAILED DESCRIPTION OF THE INVENTION

General Features and Operation

Embodiments of the present invention relate to semiconductor-chip testing apparatuses, semiconductor-chip programming apparatuses, semiconductor testing integrated-circuit chips (“TIC's”), and probe cards employable in testing and/or programming semiconductor integrated circuits. Such semiconductor integrated circuits may be hereinafter referred to as Devices Under Test (DUT's) or Devices Under Programming (DUP's).

In accordance with an aspect of the present invention, a semiconductor testing apparatus may include:

a large number of TIC's, such as ASICs (Application-Specific Integrated Circuits), designed to test a large number of DUT's;

software that generates test patterns, perhaps employing one or more algorithms;

a memory element;

a standard PC or other general purpose computer for performing tasks such as:

controlling TIC's;

loading data to the memory element;

running the test pattern generation software;

collecting and analyzing test results;

providing a graphic user interface;

presenting test results.

three types of buses for interconnecting system components;

a loading board that contains a large number of TIC's and DUT's; and

other elements used in various approaches as described below, perhaps dependent on the architecture chosen for the desired configuration or application.

A TIC, according to various aspects of the present invention may be a full tester in its nature. Each TIC may be able to perform AC, DC, functional, mixed signal (analog), and other tests. It is further noted that TICS of the present invention may be capable of performing design verification and/or characterization.

It is further noted that a TIC of the present invention may be multi-channel oriented, and therefore capable of applying the various tests described above to multiple DUT's, while performing testing of a large number of DUT's' pins concurrently and/or simultaneously, at the same time or substantially the same time, in a pipelined manner, or in a parallel manner. Each such channel may test one pin of a DUT. In other words, each TIC may represent a group of channels that can test the exactly number of DUT's pins not related to the numbers of pins that a DUT has. For example, if each TIC includes 200 channels and the a specific DUT has 50 pins, then each TIC can test four DUT's.

In this respect, the invention, depending on the configuration/application of choice, is capable of testing a large number of DUT's. For instance, in a final testing configuration, it may test up to thousands of DUT's concurrently and simultaneously. Due to the multi-channel oriented nature of a TIC according to various embodiments of the invention, one TIC may test one or multiple DUT's. Furthermore, when multiple TIC's are employed, each one of the TIC's need not test the same number of DUT's as the other TIC's. Therefore, there is not necessarily a linear relationship or fixed relationship between the number of DUT's and TIC's. The relationship between the number of DUT's and the number of TIC's can, for example, be linear or non-linear. It is possible that one TIC could test four DUT's, or more than that, or less than that. Still, the higher the number of TIC's on the loading board, the larger the number of DUT's that can be tested (and programmed) in parallel.

As mentioned above, because of the channel oriented testing, a system according to the present invention may be capable of performing (a) all DC parametric tests, (including, for example, input levels VIH/VIL, input current IIL/IIH, output level VOH/VOL, output current IOL/IOH, all chip current IDD (static, dynamic), resistive input, output fan out, high impedance current IOZL/IOZH, input clamp (IV), and output short circuit.), (b) all AC parametric tests, (including, for example, setup time, hold time, propagation delay, max/min pulse width, max frequency, output enable time, input enable time, read cycle time, and write cycle time), (c) functional test at speed, (d) mixed signals, and (e) design verification and characterization.

Regarding design verification it is noted that, in accordance with various embodiments of the present invention, a testing apparatus can characterize a DUT. In other words, it can find what the DUT limits are for each of the above parameters, using known search methodology such as binary and linear. Such a methodology might include, for example, specifying VIH (voltage input high) parameter broadcasting the same pattern with changing only the parameter VIH to identify and define what is the limit of VIH, and after that define what is the margin, and put it in the spec. Taking it another step, suppose that in the specification VIH for a DUT is 2.4 volts. If, according to the above methodology, it was found that the DUT failed at 2.1 volts, it would mean that there is a 0.3 volts margin, which is more than 10%.

In addition, the design of the apparatus according to the present invention may include formation—built in testing like CKBD (checker board). This is a feature within the TIC that enables AC parameter testing. The TIC will feed inputs, thereby performing read/write cycles. Such AC parameters include, for example, setup time, hold time, propagation delay, max/min pulse width, max frequency, output enable time, input enable time, read cycle time, write cycle time.

A system according to the present invention may provide the ability to test/program non-identical as well as different types of DUT's. For example, from the number of channels of the TIC versus those of the DUT, the present invention provides from one TIC to many DUT's, with full testing capabilities.

It is further noted that a system according embodiments to the present invention may be capable of performing both full final testing (backend testing) and full wafer level testing (wafer probing or frontend testing). It is further noted that a system of the present invention may, in certain embodiments of the present invention, be capable of performing tests on various types of ICs, including memory, logic, mix signal, RF and system-on-a-chip (SOC). The ICs tested may be either identical or non-identical, may be seated in various packages, and may have various pin counts, frequencies, functions, and the like.

Embodiments of the present invention may provide system interconnectivity that is divided into and/or based on three different, distinct bus connections: backbone (slow) bus, medium bus, and fast bus. This interconnectivity allows for resource allocation such that the TIC's can perform full testing at speed (at the same frequency) of the DUT's, in a large number simultaneously and in a cost effective manner. It is specifically noted that TIC's of the present invention may be capable of at-speed operation even when testing high frequency/high performance DUT's. In other words, a TIC may operate at high frequencies (e.g., a few gigahertz) without the need for special circuitry. In fact, a TIC may allow for “indirect signaling” such that there is no direct connection between a DUT and the computer that includes the test pattern generation software employed in DUT testing. Such functionality may allow for the use of a standard PC or other general purpose computers for testing high frequency DUT's, perhaps by using individual controllers (e.g., a low signal is transformed into a high signal through the TIC adjunct to the DUT).

Another aspect of various embodiments present invention is the placement of DUT's and TIC's on a loading board, a PCB that may connect one or more TIC's and one or more DUT's together within a short distance of only few millimeters. Such connection is made through holes in the PCB loading board. The short physical distance between the one or more TIC and the one or more DUT's can dramatically and cost effectively improve signal integrity, reduce noise, allow for increased performance using higher frequencies and increased parallelism.

It is noted that another aspect of various embodiments of the present invention, relating to the architecture, is the ability to use a standard PC or other general purpose computer rather than a mainframe or other high-performance computer. It is further noted that certain embodiments of the architecture of the present invention allow one to embed the central control on board. For example, a computer and controls can be provided adjacent to a TIC.

The present invention may in certain embodiments also provide for memory sharing using a pipeline, a full concatenation approach (for example, having one memory element that constitutes a pipeline through all the TIC's, thereby eliminating the need for a memory element for each pin of a DUT; thereby reducing costs), a limited concatenation approach, an independent approach (for example, where there is a memory element for each DUT), or an embedded approach (for example, where some or all components, such as the memory elements, are embedded into a TIC). The sharing technique implemented may depend, for example, on the configuration and/or application at hand.

As will be discussed in greater detail below, a TIC of the present invention may be composed of I/O pins, formation, a pattern generating circuit for generating test patterns, a timing measuring unit, an electric reference circuit, a failure analysis unit, a control circuit and perhaps a fast memory element.

It is noted that a TIC could, in accordance with various embodiments of the present invention be implemented as a custom IC (e.g., an ASIC), an FPGA (field-programmable gate array) with discrete components (such as operational-amplifiers (op-amps)), or using other ICs.

Yet another aspect of the present invention is that each TIC may be designed such that each of its I/O pins can support various features and functions, including: drive logic high/low, (at VIH/VIL voltage levels respectively and at the specified speed of the DUT), compare the logic high/low (at VOH/VOL voltage levels respectively), compare the logic high/low (at IOH/IOL current levels respectively), measure the current for static and dynamic measurement, and measure analog signals. With respect to current measurement, it is noted that the current following the power (VCC/GND) supporting the core of the TIC may be separated from the power of the output buffer and the power of the input buffers, thus assuring accurate reference levels.

Certain embodiments of the present invention provide a platform for process integration. Such allows for the integration of testing and burn-in processes. For example, for an application of final testing, loading boards, each containing a large number of DUT's, can be mechanically adjusted for insertion into a burn-in oven and can perform testing during burn-in. Performable tests include those of the types mentioned above (e.g., AC, DC, functional, and mixed signal), and may be performed at DUT speed. It is noted that TIC's of the present invention may perform tests on various type of ICs, including memory, logic, mix signal, and system on a chip (SOC). Moreover, tested IC's may be either identical or non-identical, and may be of various packages, pin count, frequencies, functions, and the like.

The testing process may be performed during the entire time that the loading boards are inside the burn-in oven. Each DUT may be monitored the 100% of the time, in an independent manner. Such methodology may improve the quality of the DUT's. Such methodology additionally enables one to deal with large number of DUT pins and improve throughput, thereby improving the cost of testing. It is noted that each TIC can deal with hundreds of DUT pins, and a PCB board with the size of a burn-in loading board can include on order of 100 TIC's. Thus, the system can deal with few-hundred thousand channels, and a system with many boards could deal with a few million channels individually for mast production full testing. According to embodiments of the present invention, the need for a separate final test is eliminated since all required tests are performed during the burn-in process.

Still, another aspect of the present invention is the ability to perform programming of numerous programmable semiconductor integrated circuit chips (hereinafter will be called DUT's (“DUT” referring to “device under test”) or DUP's (“DUP” referring to Device Under Programming). It is noted that the present invention allows for programming using broadcasting methodology, allowing for the use of only one set of I/O pins and reading all programmed devices in parallel. It is further noted that the present invention allows for the programming of non-identical memory devices in parallel. Such non-identical memory devices may be, for instance of different types (e.g.—NAND Flash, OTP (one time password), and serial number devices). More generally, the devices may be ones not identical in their interface, capacity, internal structure, OTPs, need for serial number, and the like. As the present invention may allow for increased parallelism not only in testing but also in programming, its application may be cost effective for mass production programming, and may deal with today growing complexity of integrated circuit chips, both in terms of packages, frequencies, high pin counts, etc

Furthermore, since the present invention allows for programming utilizing the same components used for testing, it can be performed, for instance, by automatic test equipment of the present invention, perhaps during the burn-in process, thereby implementing process integration, of burn-in, testing and programming.

According, embodiments of the present invention allow for testing, programming or both, while allowing for the integration of both stages with the burn-in process, implementing all in one stage. Such functionality may increase parallelism and/or allow for significantly increased throughput. Further allowed for is a more efficient allocation of resources that may result in reduced cost for the overall system and/or reduced cost/performance ratio.

The Testing IC and ATE Implementation

In accordance with an aspect of the invention, a testing IC (“TIC”) may perform tests including, AC test, DC test, functional test, and mixed signal (analog) test). Additionally, a TIC of the present invention can apply such tests to multiple DUT's.

Embodiments of the invention may allow one to exponentially increase the throughput of IC testing in a mass production environment, to lower total cost of ownership, and/or to improve the quality of burn-in, programming, and process integration. For instance, while most conventional ATE's can simultaneously test between four and 128 DUT's, embodiments of the present invention allow for the testing of hundreds or even thousands of DUT's in parallel, at one time. Furthermore, the total cost of ownership, including its initial purchase price, overall operating cost, and test cost per DUT, may be more attractive than that of other test systems.

Furthermore, as noted above, embodiments of the present invention allow for process integration. Accordingly, with respect to the final testing at the backend test, the embodiments of the invention allow for the integration of burn-in, testing and programming into one system. Additionally, various embodiments of the present invention allow for full monitoring of each DUT, 100% of the time, in an independent manner during manufacturing steps including but not limited to burn-in and programming processes. Accordingly, improved quality in the IC manufacturing process may be achieved.

As alluded to above, a TIC of the present invention may be capable of testing a large number of DUT's pins concurrently and simultaneously, the testing procedure being performable both at wafer probing (testing at the front-end stage) and final testing, after package and assembly.

As also alluded to above, a TIC may be employed in performing various types of IC tests (e.g., DC and AC parametric tests, functional tests, analog tests, etc.) for various types of devices, such as digital logic, memory, mixed signal, RF and analog devices, and system on a chip (SOC). Further, one TIC (or more than one TIC) may be used to concurrently and/or simultaneously test and/or program not only identical devices, but also non-identical devices (such as NAND Flash devices) as well as different types of devices (e.g., different architectures, different packages, different pin counts, different testing and/or operating frequencies, different time sets, and/or different functions, etc.).

As will be appreciated, as used herein, concurrently and/or simultaneously does not necessarily require that signals to different pin channels and/or different DUTs or DUPs are strictly synchronized such that the same or corresponding signals occur at essentially the same time (though in certain implementations they may be), but more generally refers to providing signaling in an overlapping manner or at substantially the same time, such as in a parallel (but not necessarily clock-synchronized or lock-step) or a pipelined manner. In this respect, overall testing and/or programming operations may also be performed concurrently, simultaneously, or in parallel, without requiring that they (or the underlying signaling) begin and/or end at the same time. For example, when a single TIC is implemented such that its different pin channels are configured to test different devices, these channels may operate independently while providing signals to the different devices over an overlapping time period, and the testing of these different devices will not necessarily (and typically will not) begin and/or end at the same time.

With respect to DC test parameters, a TIC of the present invention may, for example, test the following parameters:

Parametric test name:

Input levels VIH/VIL

Input current IIL/IIH

Output level VOH/VOL

Output current IOL/IOH

All chip current IDD (static, dynamic)

Resistive input

Output fan out

High impedance current IOZL/IOZH

Input clamp (VI)

Output short circuit

With respect to AC test parameters, a TIC of the present invention may, for example, test parameters such as setup time, hold time, and recovery time.

With respect to functional test and analog test, a TIC of the present invention may, for example, perform tests that will confirm that a DUT will perform its intended function according to its specifications.

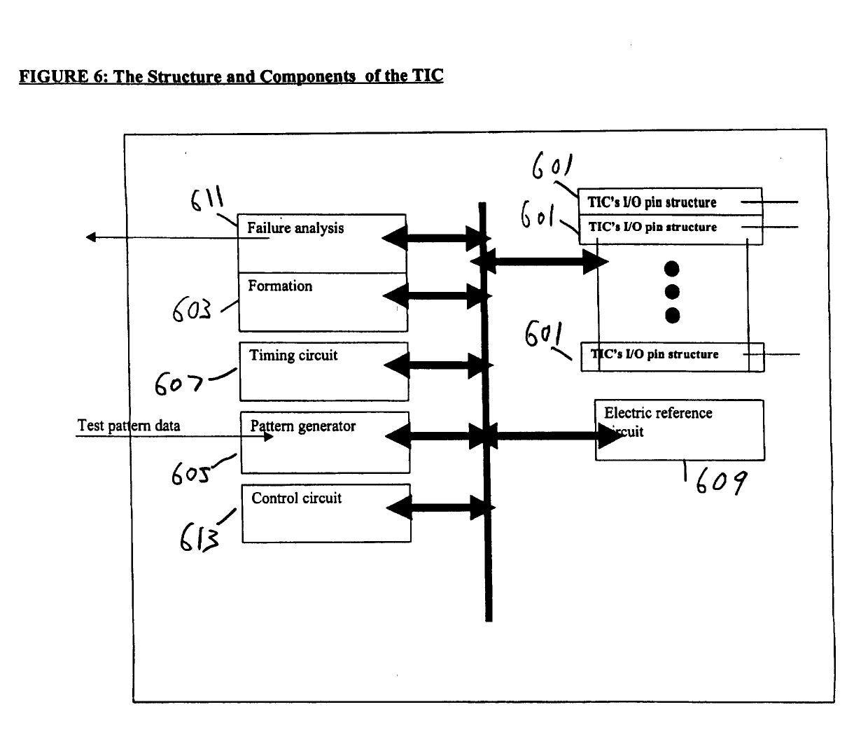

FIG. 6 schematically depicts illustrative components of a TIC in accordance with an illustrative embodiment of the invention. Shown in FIG. 6 are the following components:

1. I/O pins (601): connect the TIC to the DUT's pins;

2. Formation (603): formation contains all the various possibilities of the time-set of the DUT. Each time-set contains the timing structure of an electrical cycle, for example, at a time defined “X”, the data from address “Y” should be valid; otherwise—the electrical cycle failed;

3. Test Pattern Generating Circuit (605): drive logic level to the TIC's I/O pins according to the test pattern data;

4. Timing Measuring Circuit (607): the controller for timing activities;

5. Electric Reference Circuit (609): the controller for references of accurate voltage and current levels;

6. Failure Analysis Unit (611): analyzes the operation of the DUT and decides whether or not its performance meets requirements;

7. Control Circuit (613): coordinates the operation of the above elements.

8. Fast Memory Element: this optional component may be employed instead of connecting an external fast memory element to a TIC.

A TIC of the present invention, as stated above, may be implemented as a custom IC (e.g., an ASIC), an FPGA with discrete components (such as op-amps), or using other ICs.

It is noted that various implementations of a TIC may not include or require all of these components (e.g. fast memory element, failure analysis). It is also noted that additional components may be included and/or associated with a TIC; for example, it may include additional signal processing circuitry and/or additional memory separate from that used for storing test patterns. Such memory, for example, may be used to hold certain automatic test functions and/or to store a representation of defective memory cells generated by the TIC during programming operations. Furthermore, it is noted that while a TIC may advantageously be implemented as a single IC, it may instead be implemented as two or more integrated circuits or components (e.g., some of the functional components of a TIC may be implemented as a separate integrated circuits).

TIC's of the present invention can be used within an ATE performing final testing. Such TIC's may also be utilized for other stages of backend process, such as full test during burn-in Such implementations allow for the testing of multiple DUT's utilizing one TIC. In a typical configuration, the tester can test up to thousands of DUT's simultaneously. As alluded to above, a ATE according to certain embodiments of the present invention may have the following exemplary components:

1. A shared memory element—fast memory (e.g. SRAM) that contains all the data for the test patterns, utilized through various approaches;

2. Testing ICs (“TIC”) that can test many DUT's in parallel;

3. Software that generates test patterns;

4. A computer, for:

a. Loading the data to the memory element;

b. Analyses of the test results;

c. Graphic user interface; and

d. Presenting the results.

5. Three types of buses: slow, medium and fast.

6. A board which contains multiples DUT's as well as multiple TIC's.

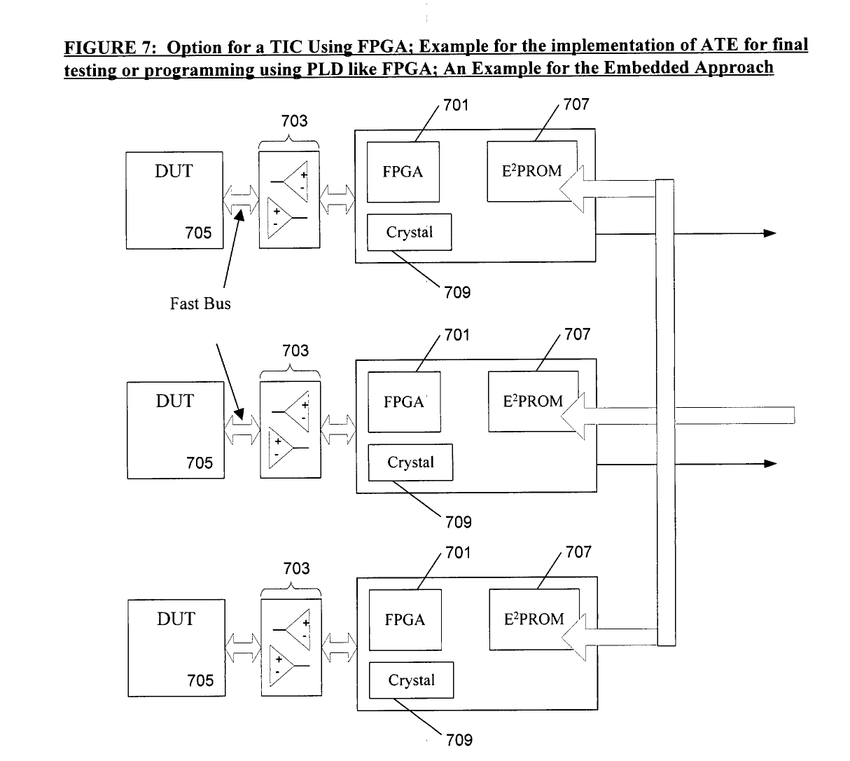

Shown in FIG. 7 is an exemplary implementation of ATE (automatic test equipment) according to embodiments of the present invention. The implementation of ATE for final testing or programming can be done using PLD (programmable logic devices), such as FPGAs (701), by placing the analog elements (703)—the comparators—outside the PLDs as discrete components. Each PLD, when joined with an appropriate analog component such as an operational amplifier, can function as a TIC. The analog devices are connected to the DUT's (705) to generate or compare the signals at certain voltage, as well as for A/D and D/A converting. In this figure the implementation is of the embedded solution, with each PLD device containing a memory element and the computer communicating with each PLD.

When implementing a TIC using a FPGA, an E2prom (707; electrically erasable programmable read-only memory) is needed to configure the FPGA. In addition, a crystal (709) is required to generate the clock.

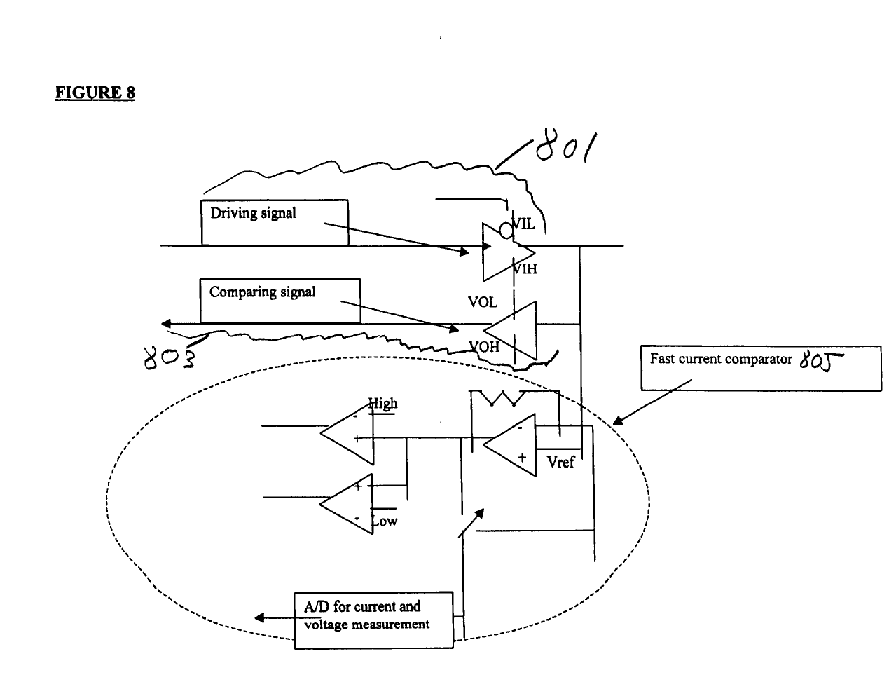

Shown in FIG. 8 is the structure of an exemplary TIC I/O pin according to embodiments of the present invention. Such pins may be designed so that each pin of a TIC can support various features/functions, including:

Driving logic high/low, at VIH/VIL voltage levels respectively, at the specified speed of the DUT (801);

Comparing the logic high/low at VOH/VOL voltage levels respectively (803);

Comparing the logic high/low at IOH/IOL current levels respectively;

Measuring the current for static and dynamic measurement. It is noted that the current following the power (VCC/GND) that supports the core of the TIC is separated from the power of the output buffer and the power of the input buffers, thus assuring accurate reference levels; and

Measuring analog signals

In order to perform the functionality required from a TIC's I/O pins, the TIC may need to get accurate references voltages. Such may be obtained, for example, from an electric reference unit.

VIH and VIL of FIG. 8 are the reference voltages for the output buffer. The output buffer may be powered using two accurate and different voltage references. When the input to the output buffer will is 1-logic (i.e., Boolean “yes”), the p channel of the output buffer will connect the TIC pin to the accurate voltage level VIH from the electric reference unit, and the n channel will be disconnected.

When the input to the output buffer will be 0-logic (i.e., Boolean “no”), the n channel of the output buffer will connect the TIC pin to the accurate voltage level VIL from the electric reference unit, and the p channel will be disconnected. In this way, the output buffer may drive the logic “1” and logic “0” in VIH/VIL levels. Such an implementation results in performance like that provided by conventional final test equipment. The pin is also connected to fast current measurement unit (805) and to A/D converter for analog signal measurement. The input buffer may be powered using two accurate and different voltage reference. Thus, the 1-logic level threshold will be VOH and the 0-logic level will be VOL.

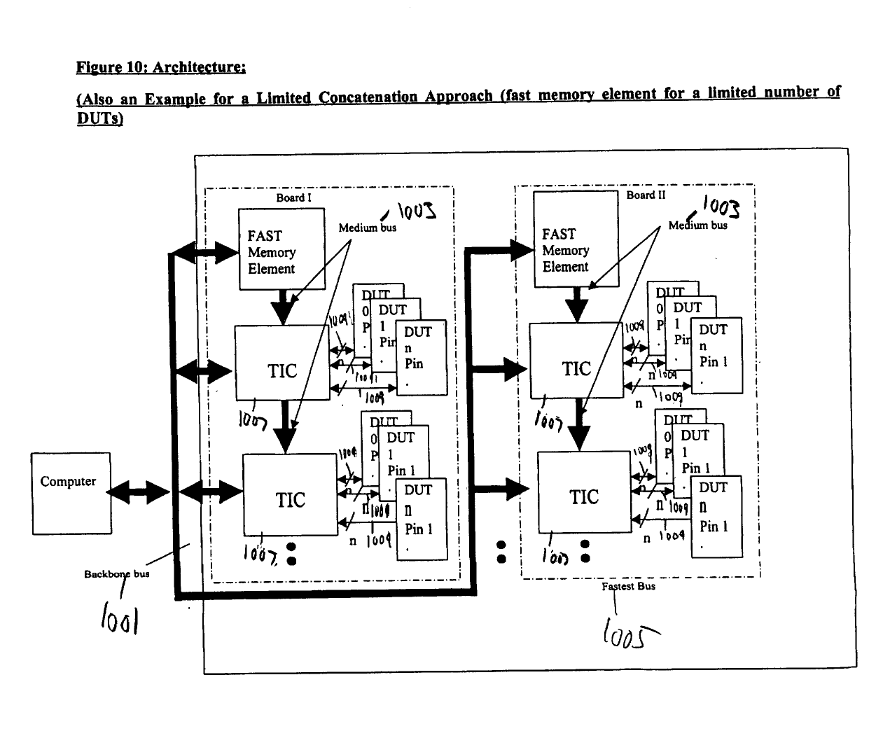

As shown in FIG. 10, system interconnectivity may, as noted above, be divided into and/or based on three different, distinct bus connections:

a. Backbone bus (1001)—connects the computer to the memory element and to the backside of the TIC. It may work only offline, thereby working at a very low frequency (1-8 MHz). Such an approach may enable the testing system to operate at maximum speed with cost effective resources. Since it works offline, processes and decisions need not be executed at DUT speed. Accordingly a low frequency system can be employed, allowing for the use of a less expensive computing system to replace the mainframe common in a conventional tester.

In addition, since the interface between the computing system and the TIC's is offline, it is possible to put the computer at a distance from the testing IC without using complex electronics.

b. Medium bus (1003)—concatenates the data from the memory element to the TIC's. The width of the medium bus may be a multiple of the width the fast bus. For example, if the fast bus is 8 bit data bus, and medium bus is 64 bits, then the medium bus can operate 8 times slower then the fast bus. Accordingly, if the medium bus operated at 800 MHz (5 ns cycle time) the tester cycle could be 6.4 GHz. Therefore, the cost of the memory element could be much lower than in conventional systems.

c. Fast bus (1005)—connects the TIC front to the DUT's and operates at the same frequency (speed) as that specified for the DUT. As a result, it allows for functional testing of each DUT at its specified speed.

FIG. 10 will be discussed in greater detail below. It is noted, however, that while this illustrative bus architecture advantageously implements the medium bus at a speed that is intermediate to the backbone and fast bus, the present invention is not limited by the medium bus having such an intermediate bandwidth. For example, depending on various factors (e.g., the speed specified for the DUT, the cost of memory, the concatenation configuration, etc.), it is possible that the medium bus may operate at a speed slower than the backbone bus or as fast as or faster than the fast bus. In typical implementations, however, the medium bus speed is intermediate to that of the backbone bus and fast bus.

Test operation, according to various embodiments of the present invention, may be divided into stages that occur offline and stages that occur online.

Stages that occur offline may occur before or after the testing process actually occurs. Prior to testing, the computer may upload all test pattern data to a memory element and all possible time-sets to the TIC's (e.g., to the formation unit inside the TIC's). After testing, results are collected from the TIC's. Stages that occur online may occurs at the same time of the testing process itself. As alluded to above, there are various alternative to this operation including a full concatenation approach, a limited concatenation approach, an independent approach, and an embedded approach.

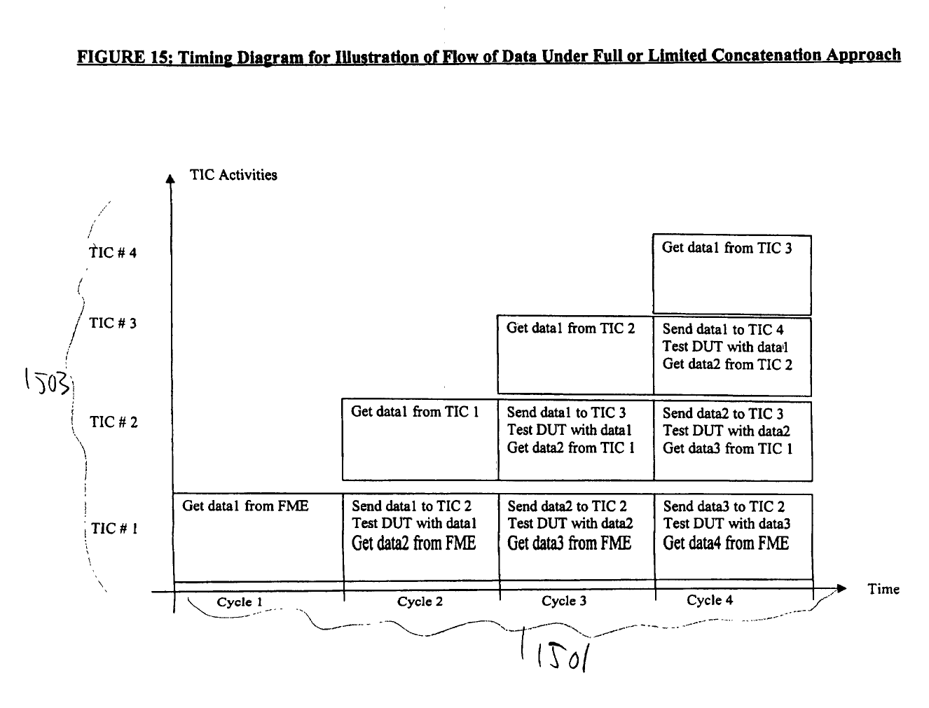

According to the full concatenation approach, at the beginning the first test pattern data may be sent from a memory element to the first TIC only. The first TIC may then use the first pattern data to concatenate the data to a second TIC and to test the DUT's attached to it using the first test pattern data. The second TIC, upon receiving the data, will, in a manner analogous to the first TIC, concatenate the data to a third TIC and test the DUT's attached to it using the data. As may be seen in FIG. 15, similar actions are performed for a fourth TIC, a fifth TIC, and so on.

By concatenating data, a system of the present invention needs only one fast memory element, and not a memory element dedicated for each pin. The memory element can work at about ⅛ of the DUT frequency.

The limited concatenation approach employs a structure of concatenation similar to that of the full concatenation approach between, for instance, a first TIC and a second TIC. However, for every n devices (whereby n is defined based on various parameters, such as n TIC per board, n determined arbitrarily, and the like), there is a fast memory element dedicated to these n TIC's.

The independent approach differs from the concatenation approaches above wherein there was only one fast memory element that concatenate the test vectors to the consecutive DUT's. Under the Independent Approach there is a fast memory element attached to each TIC.

In the embedded approach there is a fast memory element next to each DUT, with no concatenation. In such a case the memory is embedded within the TIC. It is noted that FIG. 7 represents an example of the embedded approach.

It is noted that IC testing may be required for every pin of a DUT, and may need to operate at least at the same frequency as the DUT's in order to check the DUT at its specified frequency.

Other testing systems perform testing for each pin such that it is necessary to stop the testing procedure prior to testing each pin in order to download the appropriate test pattern or patterns. According to a feature of an illustrative embodiment of the present invention, specifically when only one memory element is being used, portions of the system can operate at much lower frequencies. As a result, the memory element may be much lower in cost and have enough space for the download of all the test pattern data. Another benefit of loading all the test pattern data to the memory element may be that the data stays at the memory element even when changing the DUT's to new ones, without the need to load the pattern again. Since one download can be applied to all batches, where each batch can include many ICs), this can significantly reduce testing time. It is noted that such a configuration allows for the use of a standard PC rather than a mainframe or other high-performance computer. Additionally, as opposed to the “Per Pin Resource” approach whereby each channel is dedicated to each pin, a TIC may be used to perform the functions of hundreds of channels.

As noted above, the physical connection between a memory element, a TIC, and a DUT, may be very close (a few mm), and these elements may be mounted on the same board. As also noted above, due to their close proximity, the bus that connects the fast memory to the TIC can operate at high frequencies (few Gigahertz), without the need for special circuitry. As a result, the need expensive circuitry may be eliminated.

Furthermore, the short physical distance between the TIC and the DUT's may dramatically and cost effectively, improve signal integrity, reduce noise, allow increased performance (e.g., using higher frequency), and increase parallelism.

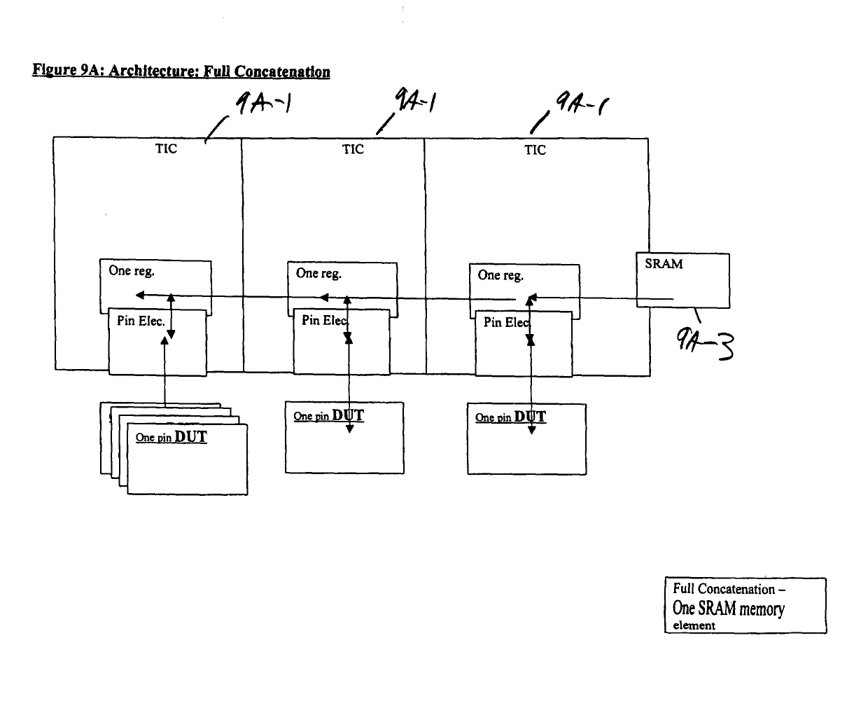

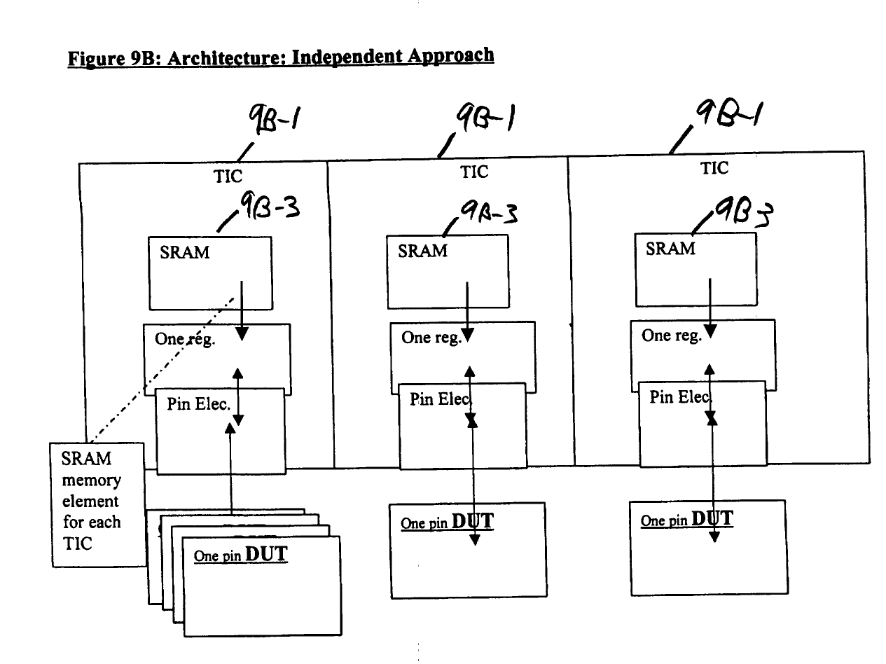

FIG. 9A illustrates an embodiment of the invention architecture representing an example of the full concatenation approach. Shown in FIG. 9A are three TIC's 9A-1 and a single SRAM memory element 9A-3. FIG. 9B illustrates an embodiment of the invention architecture representing an example of the independent concatenation approach. Shown in FIG. 9b are three TIC's 9B-1, each having its own SRAM memory element 9B-3.

Shown in FIG. 10 is an exemplary implementation of ATE for final testing and/or programming. This implementation represents an example of the limited concatenation approach. In this figure, there is an example for two loading boards bounded by a broken line. Each board implements the full concatenation approach, which is based on one memory element only. In each board there are TIC's (1007) that support multiple DUT's. Each DUT is connected to the TIC separately, by a fast bus. The TIC is concatenated from the memory element using the medium bus (1003), which works slower then the fast bus (1009). All the TIC's are connected through the backbone bus (1101) to the computer (PC). The backbone bus is the slowest bus and works only offline. The TIC sends the test results to the computer and the computer triggers the start of the various tests. The computer may make use of a GUI (graphical user interface).

The test patterns may be loaded from the computer to the memory element. It is noted that using this implementation the full boards, with the TIC's and mounted DUT's, can be inserted into an oven for full burn-in testing and programming integration.

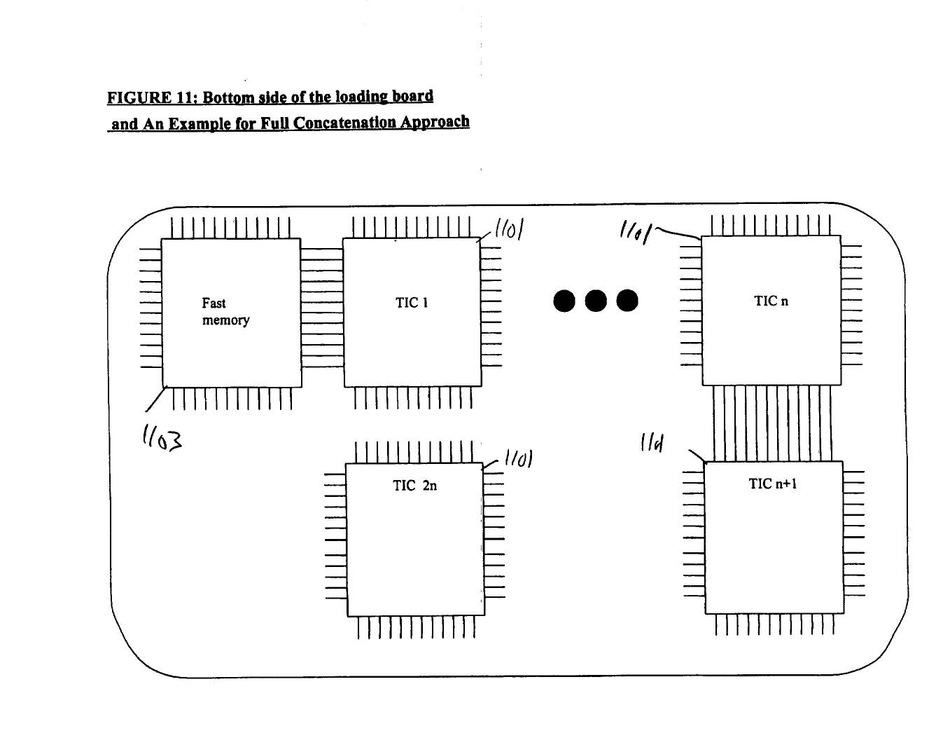

Shown in FIG. 11 is a bottom view of an exemplary loading board employable in embodiments of the present invention. The architecture represents an example of the full concatenation approach. At the bottom side of the board, all the TIC's (1101) are concatenated together. Shown also is fast memory element 1103. One of the reasons for employment of full concatenation in this embodiment is the small distance between each TIC. Such a short distance enables an increase in the frequency of the test pattern data concatenated between all TIC's and a reduction in data cycle time, thereby increasing the performance of the entire tester. Above each TIC, across the board, there are DUT's that will be tested by the TIC. Also here, there is a very short distance between each DUT and the correspondent TIC. In conventional ATE, the distance between the testing element and the DUT's ranges from few centimeters to dozens of centimeters. Embodiments of the invention allow for a much shorter distance (e.g., a few millimeters).

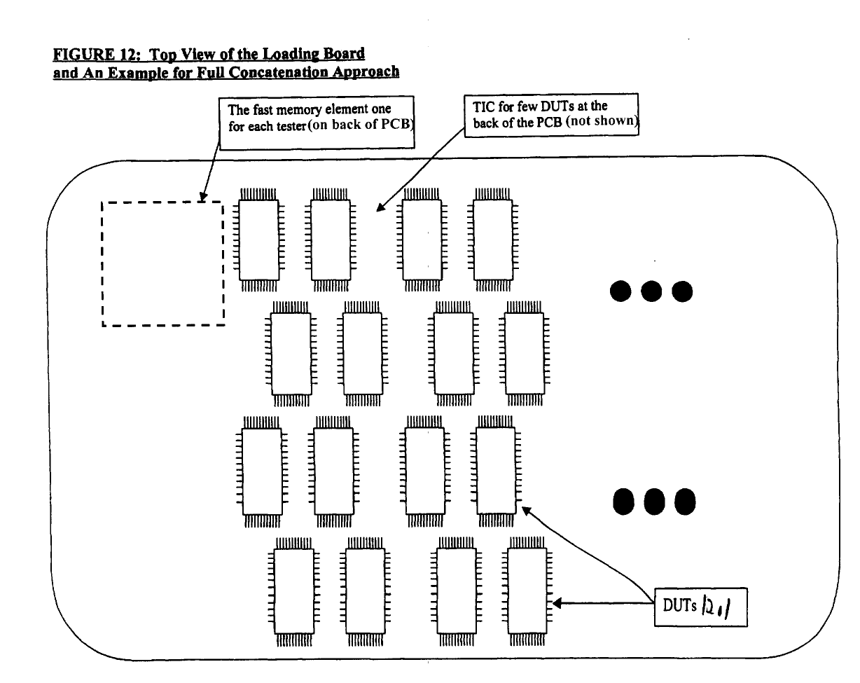

Shown in FIG. 12 is a top view of the exemplary loading board of FIG. 11. The upper side of the board contains all the sockets for the DUT's 1201, which are located directly above the TIC and are only few mm close to the TIC. As noted above, this approach allows for an increase in the frequency and the performance of the entire ATE. The gray graphics represents the approximate location of the TIC's; in this case, as an example, there is one TIC against four DUT's).

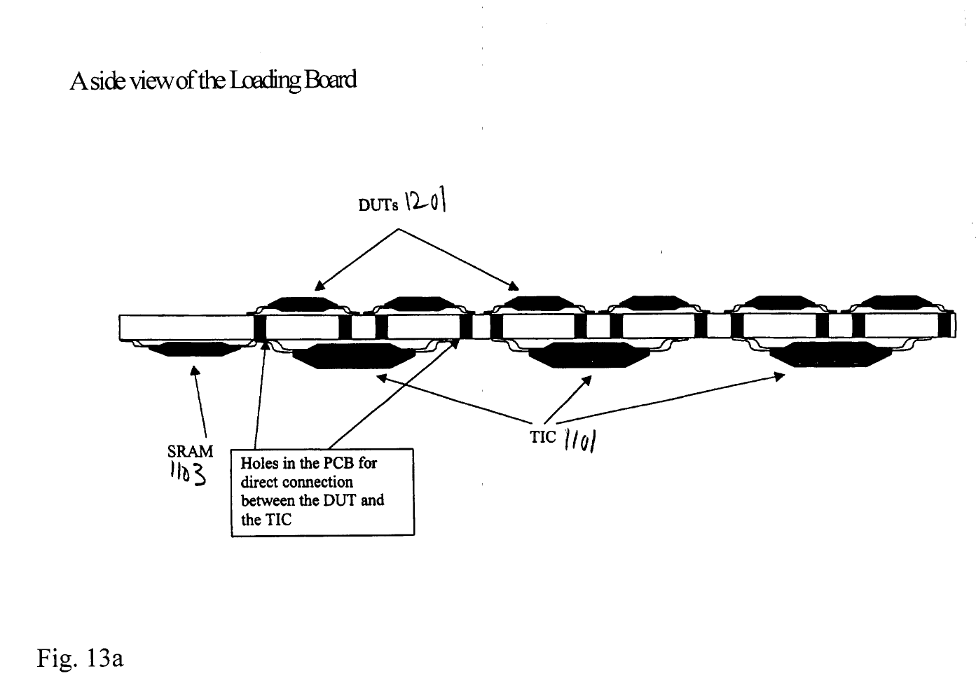

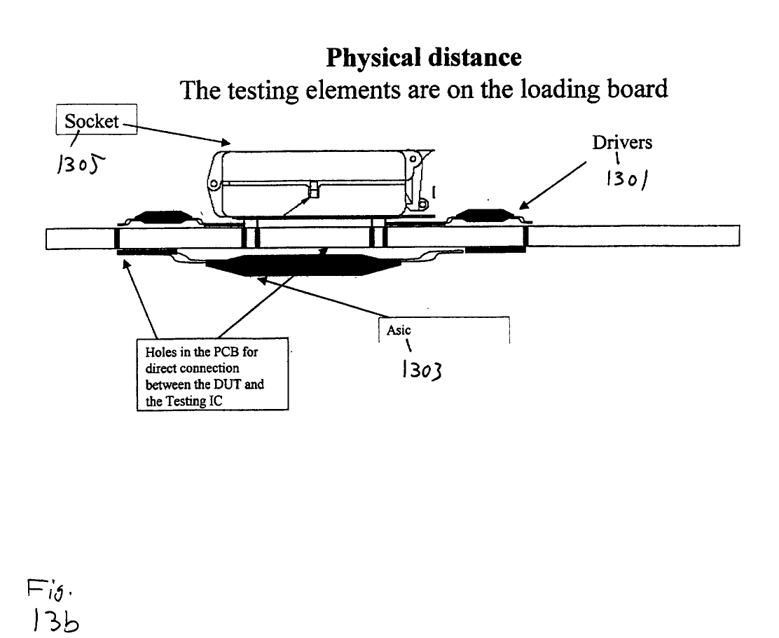

Shown in FIG. 13a is a side view of the exemplary loading board of FIG. 11. This figure shows a side view of the loading board. The loading board is a PCB board that connects the TIC's (1101) and the DUT's (1201) together within a short distance of only few mm. The connection is made through holes in the PCB. Shown in FIG. 13b is an exemplary loading board including drivers 1301, an ASIC 1303, and a socket 1305. Socket 1305 could be employed, for example, in holding one or more DUTs.

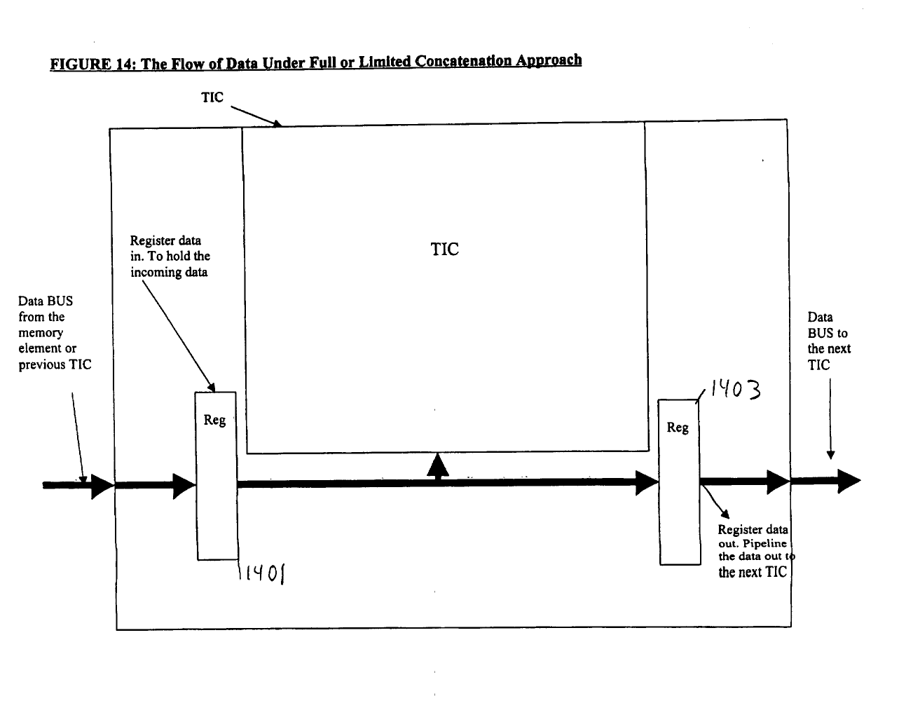

FIG. 14 is a flow diagram corresponding to a full-concatenation or limitedconcatenation approach according to embodiments of the present invention. The test pattern data is coming from the previous TIC or from the fast memory element, into a register/latch (1401). The register/latch is located near the relevant pins, and then continues into the inside of a TIC as well as to the far (next) register/latch (1403) and then out from the TIC to the next TIC. The current data flow is broken into pipeline-like stages. To reduce the complexity, the TIC has to do each data cycle. The reason for breaking the whole data flow into small stages is to increase the data flow frequency and improve the overall testing rate/frequency.

FIG. 15 is a timing diagram corresponding to a full-concatenation or limited-concatenation approach according to embodiments of the present invention. The x-axis (1501) indicates time. It is divided into data cycles in a generic manner, which could be synchronous or asynchronous. The y-axis (1503) indicates the TIC numbers (identity). From the y-axis one can find which TIC is doing what action in which cycle, with the relevant action being described inside the rectangular box. For instance, in the first data cycle, only TIC No. 01 is performing an action, which is receiving the data into the incoming register. In the next data cycle (cycle #2), the TIC No. 01 perform the actions of transferring the pattern data into the TIC and to the outgoing register, testing the DUT with data 1, and receives the next data (data 2) into the incoming register.

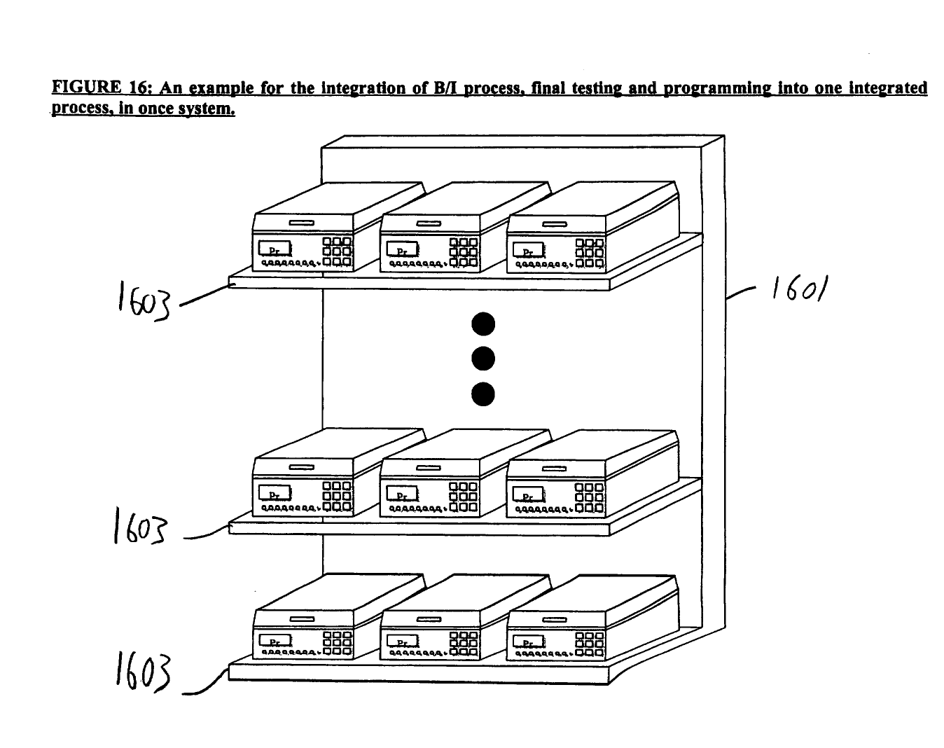

FIG. 16 illustrates aspects of an embodiment of the present invention wherein burn-in, testing and programming are integrated into one process within a burn-in oven. In this picture, the boards are mounted on a rack (1-601) as shelves (1603) to be inserted into an oven.

The system utilizes the TIC within the board. The board can be mechanically adjusted for insertion into a burn-in oven, and can perform the final test during the burn-in (B/I) time. During the burn-in, all testing parameters—AC, DC, Functional and analog—can be performed by the TIC's at the speeds and conditions specified for the DUT's. Further, the TIC's can monitor the DUT's during the entire burn-in process, 100% of the time, in an independent manner. As a result, this methodology will improve the quality of the DUT's.

The new methodology enables one to deal with large number of DUT pins and improve the throughput, thereby improving the cost of testing. Each TIC can deal with hundreds of DUT pins, and a PCB board with the size of B/I board can includes 100 TIC's. Thus, the system can deal with few 100K of channels and a system with many boards can deal with few millions channels individually for full testing for mass production.

During burn-in, the DUT's undergo all the final testing and programming needed. Each board in this example has a shared memory element of the sort noted above, a TIC of the sort noted above, a computer of the sort noted above, and slow, medium, and fast buses of the sort noted above.

Unlike other solutions, embodiments of the invention may be based on TIC's utilizing the “Shared Resource” approach. In certain test systems currently in use, the approach is per pin and the DUT's are not monitored 100% of the time. Furthermore, such current test systems are not capable of performing all required tests, and therefore separate final tests must be performed.

According to the invention, the need for a separate final test is eliminated since all required tests are performed during the burn-in process.

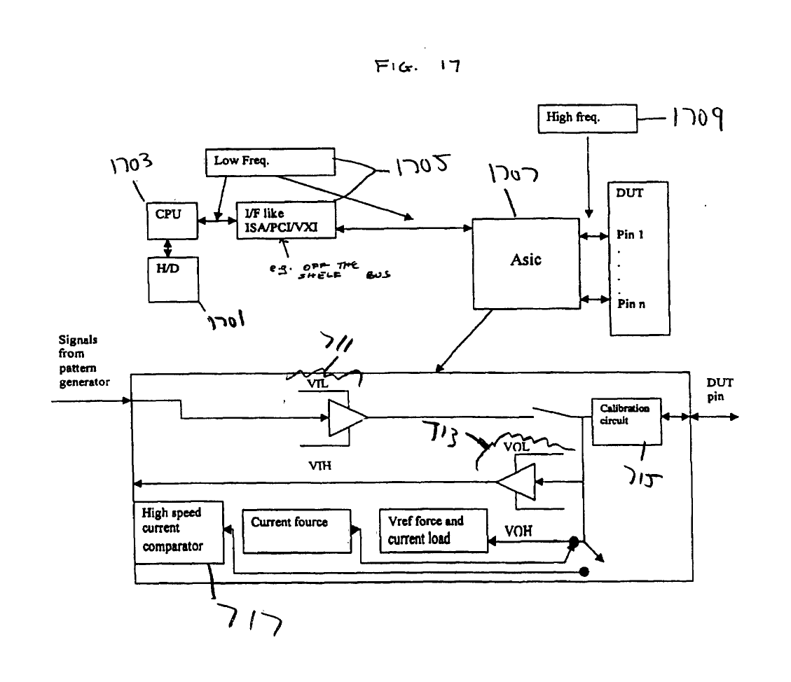

Shown in FIG. 17 is an exemplary ATE system architecture according to embodiments of the present invention. Shown in FIG. 17 are hard drive 1701, CPU (central processing unit) 1703, slow bus 1705, ASIC 1707 (i.e., a TIC implemented as an ASIC), fast bus 1709, drive logic 711, compare logic 713, calibration circuit 715, and high-speed current comparator 717. As understood, the lower portion of FIG. 17 shows illustrative circuitry associated with a given pin channel in ASIC 1707 (each of the pin channels having its own corresponding such circuitry), the circuitry providing test signals to the DUT (via the DUT pin) in response to signals generated by the ASIC's pattern generator, the circuitry also receiving signals from the DUT for measurement, processing and/or characterization by the ASIC (TIC).

TIC Use in Programming Applications

As alluded to above, to perform IC programming, TICs may be implemented (e.g., architected) in a manner similar to that described above with reference to IC testing. For instance, IC programming may be implemented using the same TIC and related components described above with reference to final testing. One result of this is that such a programming system may additionally be able to perform testing elements of the devices being programmed. More specifically, commonly used test patterns such as program/erase cycles, checker board checks, DC testing, AC testing, and functional tests may be performed. In a one exemplary aspect, TIC's may be so employed to perform programming on a stand alone basis.

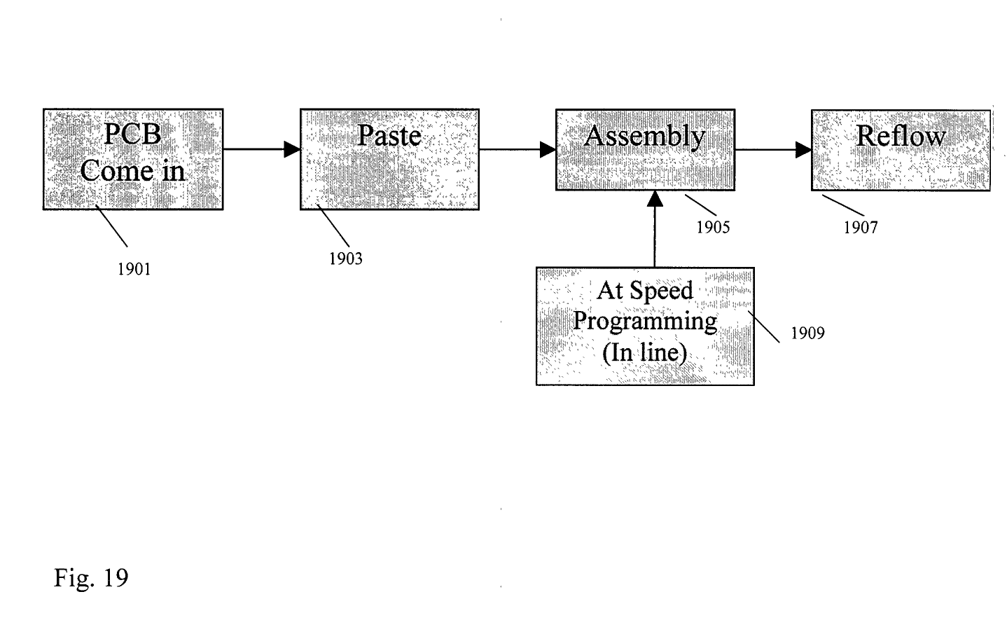

In offline stand alone programming, a system of the present invention may perform IC device programming at its own pace, the resultant programmed devices perhaps becoming part of an inventory. On the other hand, in online/inline programming, a system of the present invention may perform IC device programming as part of the production line and/or assembly line for final products. Such an assembly line may be, for example, an SMT assembly line where electronics components, including the programmed ICs, are assembled onto printed circuit boards. Unlike a programming system wherein ICs are already pre-programmed before coming to an assembly line, an online and/or inline programming system is part of an assembly line, and may be employed to perform just-in-time programming of ICs just before the ICs are assembled and/or placed onto a PCB. Depicted in FIG. 19 is an exemplary production flow for an assembly line, the flow including the steps of a PCB coming into the assembly line (step 1901), paste (step 1903), assembly (step 1905), and reflow (step 1907), with at-speed programming being performed inline (step 1909). As alluded to above, the present invention may allow for the simultaneous programming of a large number of ICs. Such functionality may act to prevent production line delays and programming bottlenecks. Furthermore, it is noted that the invention may provide for the implementation of process integration, for example, by allowing for programming in combination with an ATE performing final test application, and/or by allowing for programming in combination with an ATE performing final test application during the burn-in process.

An exemplary programming operation may be thought of as having two phases, writing data in and verifying the data. It is typically possible to employ a single bus in performing the writing phase with respect to many devices. However, it is typically not possible to employ a single bus in performing the verify phase with respect to many devices. Accordingly, in order to verify data-from a device, a programmer may need a separate bus for each device. One reason that a single bus is typically not employable in performing the verify phase is that it is typically necessary to know which device has an error. Using common bus for reading will blocks the ability of a programmer to identify the faulty device. Another reason is that a faulty device may return different data, which may likely lead to bus contention.

For many conventional implementations, the cost of programming and verifying in parallel is nearly linear to the numbers of device in parallel. However, such may not be true for embodiments of the present invention. As alluded to above a TIC of the present invention may supply a bank of a plurality channels. As a board may include multiple TIC's, a large number of channels may be provided. Such may allow for high parallelism in programming.

As noted above, a TIC of the present invention may be interconnected through an independent fast bus to a DUT. Such a DUT need not be connected to anything else, allowing for the execution of verification in parallel and independently for each DUT. As such an implementation provides separate busses, bus contention may be avoided.

As also noted above, currently available programming systems may fail to perform programming to a large number of devices in parallel. It is further noted that, with currently available programming systems, programming time may increase with increased memory capacity. This may result in decreased throughput. More specifically, with currently available programming systems it can take up to few minutes to program a high-density IC, such as a flash memory IC. Long programming time may increases the total IC cost. Accordingly, with respect to currently available programming systems, it might be said that as the density of memory chips has increased, programming time has become a bottle neck.

In contrast, embodiments of the invention may increase throughput exponentially by the ability to program a multitude of DUP's. As a result, the overall time for programming a given number of DUP's may be reduced.

With further regard to the verification phase of programming, two techniques for executing this stage will now be discussed. The first will be referred to as “checksum command”, while the second will be referred to as “full read/full verify”.

Executing of the checksum command may act to activate a “checksum” command and/or process, but does not guarantee that all aspects were programmed successfully. “Checksum” is a simple final check, a count of the number of bits in a transmission unit that is included with the unit so that the receiver can check whether or not the complete transmission was received. If the count match, it is assumed that the same number of bits arrived and the transmission completed successfully. Otherwise, it is assumed that there is a transmission error.

On the other hand, execution of full read/full verify activates a full reading of the entire program from the flash device. The full read/full verify approach may, for at least this reason, be thought of as being superior to the checksum command approach. Yet there is typically a significant difference in time between checksum command and full read/full verify, the latter taking longer. In addition to full read/full verify, sometimes it is required to perform an erase operation, thereby further increasing the time required. However, embodiments of the present invention allow for the execution of a full read/full verify and erase to a large number of ICs in parallel, thereby performing the full process of full read/full verify and erase, at a reduced time.

To at least a certain extent, with new generations of ICs has come an increase in IC pin count. For example, while past IC interfaces may have been typically limited to 8 bits, wider interfaces, such as 32-bit and 64-bit interfaces, appear to be coming increasingly common. Such increases in interface width tend to require a substantial increase in pin count. This means that the number of channels needed to program and/or test a device can be very high. Current solutions tend to require a dedicated channel for each pin, and this may significantly increases costs. From another point of view, increase in IC pin count can be thought of as decreasing the number of ICs a conventional programmer can handle. For instance, a conventional programmer with 1024 channels that can deal with 16 memory devices with 64 pins each can only with only four memory devices with 256 pins each.

In contrast, programmers designed in accordance with the present invention may not suffer from such problems. Due to the high number of channels offered by TIC's of the present invention, such programmers may be able to interoperate with high pin count devices, and/or conduct programming cost effectively and/or with less resources than are required by other techniques.

It is also noted that, to at least a certain extent, with new generations of ICs has come increased complexity. For instance, a contemporary memory IC, instead of being used on stand alone basis, may be integrated, for instance, with a SOC (system-on-a-chip), CPU (central processing unit), PLD (programmable logic device), DSP (digital signal processor), or the like. Such devices tend to be complex, and, what is more, typical speed (i.e., frequency) appears to be getting higher.

In order to program a memory component of such a device, it is generally necessary to interoperate with the entire device, including its internal modules, at the speed the device operates at. Accordingly, more then simple CPU may be necessary to reach the cycles of such a DUP.

In contrast, programmers designed in accordance with the present invention may not suffer from such problems. As noted above, TIC's of the present invention may offer a high number of channels. Furthermore, the present invention allows for the sharing of resources (e.g., the memory element, the three buses). Accordingly, a programmer designed in accordance with the present invention may be able to interoperate with such high-pin-count devices, and/or conduct programming cost effectively and/or with less resources than are required by other techniques.

It is further noted that many patterns may be required in order to perform programming of complex devices. Accordingly, conventional approaches may require a long load time for patterns. However, by employing a large capacity memory element or the sort described above, the system of the present invention can require fewer pattern downloads. For instance, “burst” loading of patterns can be employed to reduce the number of downloads.

Furthermore, the present invention may provide a fast waveform generator that can build 20 ns cycles with a bit rate of 1.6 Gbit/sec for a 32 bit interface. Such a waveform generator can send a sequence to a driver of the present invention, which can in turn translate the logic data to compliant levels (VIH/VIL) of the IC. The waveform structure may be transformed to time-sets, perhaps eliminating the need to define the timing for each data pattern. It is further noted that embodiments of the invention can act to integrate at-speed failure analysis with DSP core technology, allowing for the analysis of data and the use of failure analysis results in pattern command.

Failure analysis may, for example, provide for the error detection, bad block recognition, and error map detection. Failure analysis may allow for the writing of complex patterns that can execute commands and/or parameters for finding inconsistencies such as bad blocks. Commands may include, for example, skipping bad blocks, changing pointers, and writing bad block tables. Various of these aspects will be described in further detail below.

There appears to currently be no available solution for the parallel programming of non-identical integrated circuits, such as NAND Flash devices which are characterized by bad memory blocks in different locations (i.e., different cells) within the device. As a result, the programming of non-identical flash devices is usually executed utilizing serial programmers, gang programmers, and the like, while the users do not perform the process in-line. Furthermore, performing parallel programming of non-identical devices typically requires not only writing of data but also identification of relevant bad blocks. Such identification typically must be performed independently for each device, and this tends to require a full resource against each device.

However, programmers designed in accordance with the present invention may not suffer from such problems. Firstly, as alluded to above, the invention may provide an algorithm to identify and/or treat bad blocks, and to deal with features like unique ID and encryption. Secondly, a programmer designed in accordance with the present invention is capable of programming non-identical IC devices. Such a programmer is capable of programming unique ID for each IC in parallel, programming individual encryption code in parallel, and performing bit map failure analysis.

With further regard to parallelism, it is noted that conventional approaches to programming a large number of ICs in parallel tend to be expensive. More specifically, in order to get enough parallelism for mass production and to meet time constraints, a manufacturer, OEM (original equipment manufacturer), programming service house, or the like typically needs many programmers in the production line and/or needs to integrate many programmers into one machine (e.g., putting a separate CPU, memory, etc. against each DUP).

However, with programmers designed in accordance with the present invention, there is no need for a separate CPU or memory element for each DUP. Furthermore, the overall architecture may allow the use of less expensive components.

As noted previously, bad block recognition may be performed in accordance with the present invention. This operation may be performed, for example, with respect to memory ICs to be programmed. Such a memory IC may be, for instance, a NAND flash IC.

Accordingly, a map, table, or the like conveying or identifying “good” (i.e., functional and/or capable of being written to) memory blocks may be constructed with reference to a memory IC to be programmed. A block may correspond to one or more memory cell. As may be appreciated, the “good” blocks may be represented or identified in various ways, such as by offsets or pointers to the next “good” cell, or by identifying defective block addresses, etc. The map, table, or the like so created may be stored in a memory location that is perhaps inside of, integrated with and/or associated with one or more TIC's that will be employed in programming the memory IC.

In most cases, the manufacturer of a memory IC may be responsible for testing its blocks and marking them as “good” or “bad” in accordance with the determination. For such a memory, bad block recognition according to the present invention may be performed by examining each block to see how it is marked. An indication of those blocks found to be marked as “good” could be recorded as a map, table, or the like of the sort noted above. Alternately, such a map, table, or the like could be populated or generated by the TIC testing each block rather than checking for a “good” or “bad” indication. In any event, each TIC is operative in generating and storing the map for a DUT (or DUP) and, as previously noted, depending on a TIC's pin configuration, a single TIC may be operative in generating and/or storing the map for more than one DUT (or DUP).

When writing to a memory IC in accordance with the present invention, a constructed map, table, or the like of the sort noted above could be employed. The table or the like could be integrated with and/or associated with one or more TIC's for programming the memory IC. In writing to the memory as many sequential good blocks as necessary could be employed, the good blocks being known from the table or the like. For example, in writing data (e.g., code) to each employed good block, the pointer associated with each such block could be made to point to the next sequential good block based on the information stored in the table, and such an operation would be iterated until all the data is written and/or the end of the memory block is reached. It is understood that the TIC map generating phase/operation and/or writing phase/operation may include steps to account for cases where the IC has insufficient “good” blocks to store the data that must be written (e.g., identify the IC as defective and/or specify how much memory it has available). More specifically, by way of example, if while the TIC is generating a map of “good” blocks by sequentially testing each memory cell/block it recognizes that the number of “bad” cells has exceeded a value such that insufficient “good” blocks remain to store the quantity of data intended to be written, then the TIC may terminate the map generating process and report to the controller that the given DUT is defective. (Of course, if the number of “bad” cells does not exceed that value, the TIC terminates the map generating process upon testing each memory cell/block, with the DUT's total available memory size and signaling requirements (e.g., time set), etc., having been downloaded by the controller.)

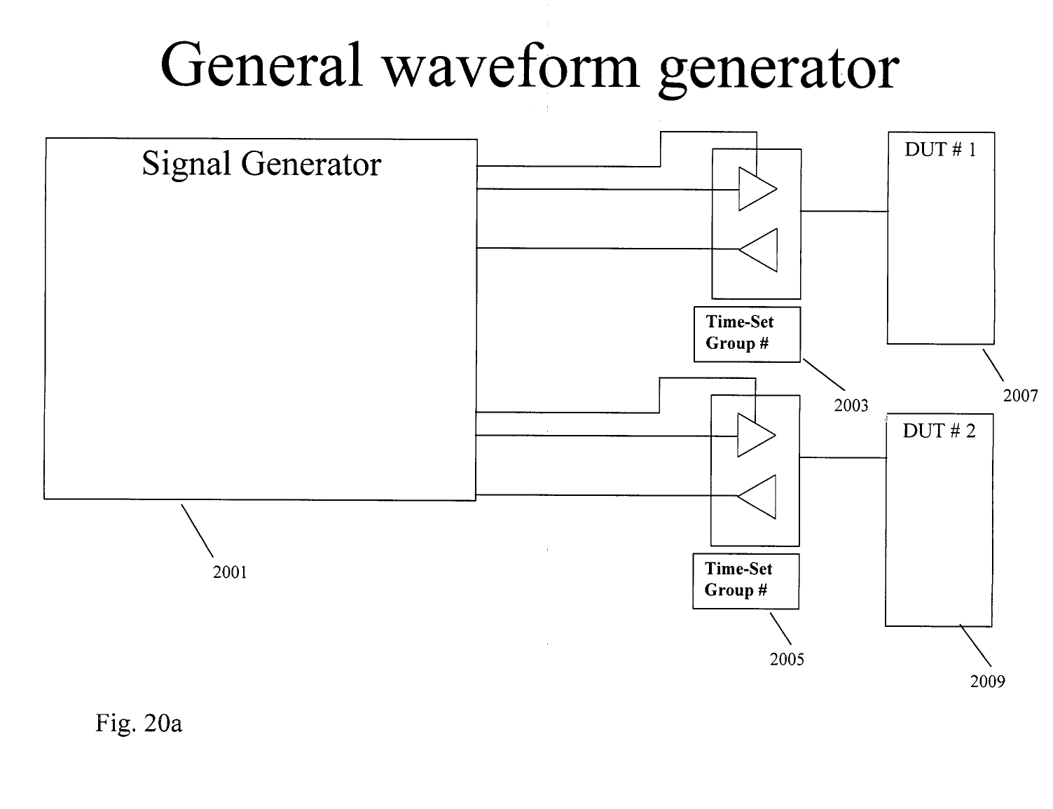

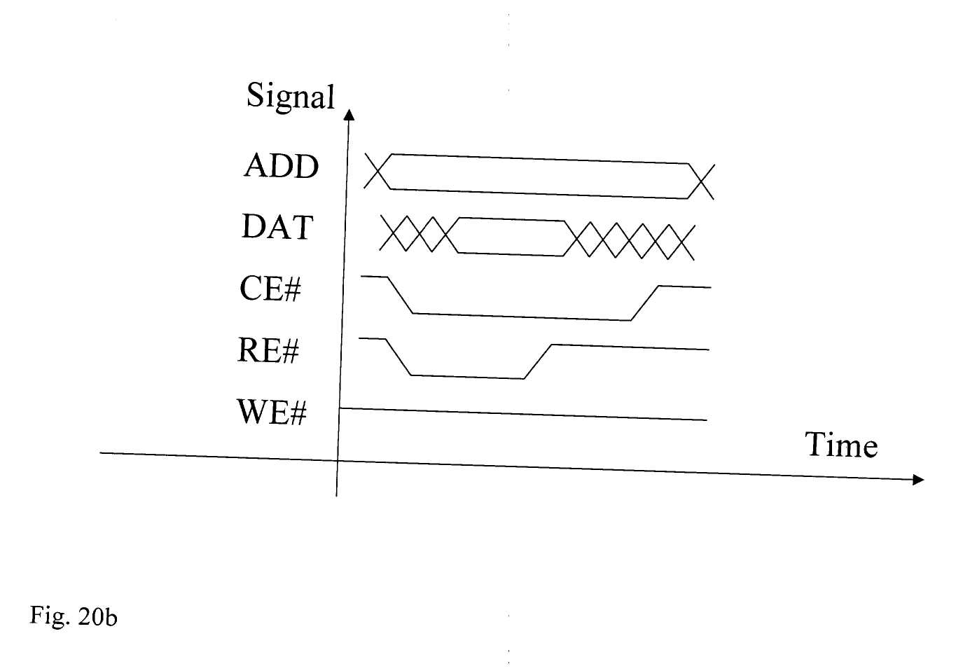

In the programming of DUT's, time sets may be employed. It is noted that a single TIC is capable of handling more than one DUT such that for each DUT there is an independent time set. It is further noted that a single TIC is capable of programming more than one DUT even in the case where the DUT's are of different types. FIG. 20a is a block diagram corresponding to an exemplary embodiment wherein a single TIC's signal generator 2001 programs a first DUT 2007 in accordance with a first time set 2003, and further programs a second DUT 2009 in accordance with a second time set 2005. FIG. 20b is a signal/time graph corresponding to an exemplary time set. It is noted that a time set may include signals such as address, data, read, write, and chip enable.

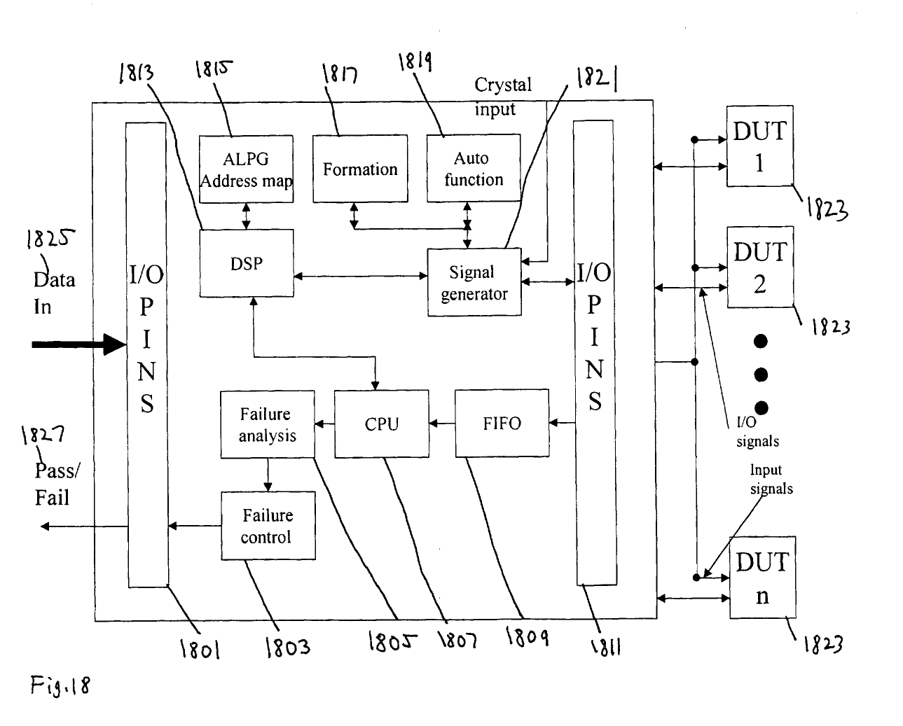

As noted previously, TIC's of the sort described above are employable in IC programming. Shown in FIG. 18 is an additional exemplary TIC employable in applications including but not limited to IC programming. Shown in FIG. 18 are I/O pins 1801, failure control 1803, failure analysis 1805, CPU 1807, FIFO (first-in-first-out) buffer 1809, I/O pins 1811, DSP (digital signal processor) 1813, ALPG (algorithmic logic pattern generator) address map 1815, formation element 1817, auto function element 1819, signal generator 1821, DUT's 1823, data input 1825, pass/fail output 1827, and crystal input 1829.

The functionally of the elements of FIG. 18 may be generally like that of their analogous counterparts described earlier. Additionally, it is noted that Address map 1815 may correspond to the above-described map or the like indicating good memory blocks of a DUT and/or address maps for tests patterns. Element 1815 may additionally include x and y registers for addressing commands. CPU 1807 may act, for example, to compare incoming data to reference, build the above-described map, and/or perform physical-to-logical address conversations.

Auto function element 1819 may act to perform certain tasks involved with the processing of a new IC, such as an open/short check. Signal generator 1821 may act to drive signals according to the outputs of, for instance, elements 1815, 1817, and 1819. FIFO buffer 1809 may act, for instance, to coordinate bandwidth in interfacing CPU 1807 with I/O pins 1811. Formation element 1817 may act as described above, including participating in the use and/or generation of time sets. Arriving through data input 1825 may be, for example, high level commands and/or inputs dispatched by a GUI (graphical user interface).

It is noted that a particular TIC may not include and/or be associated with all of these components. It is also noted that additional components may be included and/or associated with a TIC. Furthermore, it is noted that some components associated with a TIC may not be included within that TIC. For example, one or memory units may be included within and/or externally associated with a TIC. Such memory units may hold, for example, test patterns and/or indications of the good memory blocks of an IC.

Ramifications and Scope

Although the description above contains many specifics, these are merely provided to illustrate the invention and should not be construed as limitations of the invention's scope. Thus it will be apparent to those skilled in the art that various modifications and variations can be made in the system and processes of the present invention without departing from the spirit or scope of the invention.

For instance, it is noted that certain of the elements described above as being integrated into a TIC could instead be placed outside a TIC. Accordingly, the memory element described above as being integrated with a TIC could instead be placed outside of a TIC. Such externally-placed elements could be functionally connected to one or more TIC's.

What is claimed is:

1. A system for testing and/or programming at least one integrated circuit, comprising:
a controller;
a memory coupled to said controller by a first bus characterized by a first bandwidth, wherein said memory stores testing and/or programming information received from said controller via said first bus; and
a plurality of circuit modules that are capable of coupling via a third bus to test and/or program at least one integrated circuit based on the testing and/or programming information stored in said memory, wherein said third bus is capable of operating at a third bandwidth greater than said first bandwidth of said first bus.

2. The system according to claim 1, wherein said plurality of circuit modules are configured to access said testing and/or programming information from said memory via a second bus that operates at a second bandwidth less than said third bandwidth.

3. The system according to claim 2, wherein said plurality of circuit modules are configured for one of said plurality of circuit modules to directly access said memory to obtain said testing and/or programming information, and to sequentially communicate said testing and/or programming information to each of the other of said plurality of circuit modules by serial concatenation.

4. The system according to claim 2, wherein said memory is provided as a plurality of independently accessible memory units, and wherein said plurality of testing modules are organized in groups, each group having a plurality of testing modules configured (i) for one of the circuit modules in the group to directly access a respective one of the memory units to obtain said testing and/or program information and (ii) for sequential communication of said testing and/or programming information to each of the other of said plurality of circuit modules in the group by serial concatenation.

5. The system according to claim 2, wherein said memory is provided as a plurality of independently accessible memory units, and each of said circuit modules is configured to access a respective one of the memory units to obtain said testing and/or program information.

6. The system according to claim 5, wherein each of said testing modules is implemented as a respective testing integrated circuit.

7. The system according to claim 6, wherein each of the memory units is integrated on a respective testing integrated circuit.

8. The system according to claim 1, wherein each of said plurality of circuit modules is implemented as a single testing integrated circuit, the number of testing integrated circuits thereby being equal to the number of circuit modules.

9. The system according to claim 1, wherein the memory is implemented as separate memory devices each dedicated to respective circuit modules.

10. The system according to claim 1, wherein the memory is implemented as a memory device shared by said plurality of circuit modules.

11. The system according to claim 1, wherein each of said circuit modules comprises a plurality of pin channels that are each coupled to a respective node of said at least one integrated circuit, wherein different pin channels of a given one of said circuit modules can be configured for concurrently testing and/or programming different ones of said at least one integrated circuit, a given testing integrated circuit module thereby being capable of concurrently testing a plurality of said at least one integrated circuit.

12. The system according to claim 11, wherein said at least one integrated circuit includes integrated circuits having different characteristics, the given one of said circuit modules capable of concurrently testing and/or programming the integrated circuits having different characteristics.

13. The system according to claim 12, wherein the integrated circuits having different characteristics are devices that store distinct program code, the given one of said circuit modules capable of concurrently programming the distinct program code in the integrated circuits having different characteristics.

14. The system according to claim 1, wherein said at least one integrated circuit includes integrated circuits having different characteristics, said plurality of circuit modules capable of concurrently testing and/or programming the integrated circuits having different characteristics.

15. The system according to claim 14, wherein the different characteristics include different time sets.

16. The system according to claim 1, wherein each of said circuit modules comprises a plurality of pin channels that are each coupled to a respective node of said at least one integrated circuit, wherein each of the plurality of pin channels is independently capable of at least DC, AC, and functional testing operations.

17. The system according to claim 1, wherein said testing modules and said at least one integrated circuit are mounted on a loading printed circuit board.

18. The system according to claim 17, wherein said controller is mounted on said loading printed circuit board.

19. The system according to claim 17, wherein said controller is implemented as a personal computer.

20. The system according to claim 1, wherein said at least one integrated circuit are each located on a wafer.

21. The system according to claim 1, wherein said at least one integrated circuit are packaged dies.

22. A method for programming and/or testing at least one integrated circuit, the method comprising:
storing in a memory testing and/or programming information received from a controller via a first bus characterized by a first bandwidth;
accessing the stored testing and/or programming information; and
communicating testing and/or programming signals with said at least one integrated circuit to test and/or program said at least one integrated circuit, the testing and/or programming signals being transmitted to said at least one integrated circuit at a third bandwidth greater than said first bandwidth, said testing and/or programming signals being based on the testing and/or programming information accessed from said memory.

23. The method according to claim 22, wherein said accessing is effected via a second bus having a second bandwidth less than said third bandwidth.

24. The method according to claim 22, wherein said communicating testing and/or programming signals includes outputting signals to said at least one integrated circuit and inputting signals from said at least one integrated circuit.

25. The method according to claim 22, wherein said testing and/or programming signals are operative in effecting AC, DC, and functional testing.

26. A system for programming and/or testing at least one integrated circuit, the system comprising:
means for storing testing and/or programming information received from a controller via a first communication link characterized by a first bandwidth; and
means for communicating testing and/or programming signals with said at least one integrated circuit to test and/or program said at least one integrated circuit, the testing and/or programming signals being transmitted to said at least one integrated circuit at a third bandwidth greater than said first bandwidth, said testing and/or programming signals being based on the testing and/or programming information accessed from said means for storing.

27. The system according to claim 26, wherein said at least one integrated circuit includes at least one memory or programmable device, said system further comprising means for generating a representation of defective locations in the at least one memory or programmable device.

28. The system according to claim 27, further comprising means for programming said at least one memory or programmable device based on said representation of defective locations in the at least one memory or programmable device.

29. A testing and/or programming circuit module for testing and/or programming at least one integrated circuit, comprising:
a plurality of configurable pin channels each capable of being coupled to a respective node of said at least one integrated circuit;
a control circuit that is operative in coordinating the communication by each of the configurable pin channels with the respective nodes of testing and/or programming signals based on testing and/or programming information stored in a memory.

30. The testing and/or programming circuit module according to claim 29, wherein different configurable pin channels are configurable for concurrently testing and/or programming different ones of said at least one integrated circuit, thereby concurrently testing and/or programming a plurality of said at least one integrated circuit.

31. The testing and/or programming circuit module according to claim 30, wherein said at least one integrated circuit includes integrated circuits having different characteristics.

32. The testing and/or programming circuit module system according to claim 31, wherein the integrated circuits having different characteristics are devices that store distinct program code, the testing and/or programming circuit module capable of concurrently programming the distinct program code in the integrated circuits having different characteristics.

33. The testing and/or programming circuit module according to claim 31, wherein the different characteristics include different time sets.

34. The testing and/or programming circuit module according to claim 29, wherein said testing and/or programming information is accessed by said testing and/or programming module via a second bus having a second bandwidth that is less than the bandwidth for the communication by each of the configurable pin channels of testing and/or programming signals to the nodes.

35. The testing and/or programming circuit module according to claim 29, wherein said testing and/or programming information is stored in said memory by a controller via a first bus having a first bandwidth that is less than the bandwidth for the communication by each of the configurable pin channels of testing and/or programming signals to the nodes.

36. The testing and/or programming circuit module according to claim 29, wherein each of the plurality of pin channels is independently capable of at least DC, AC, and functional testing operations.

37. The testing and/or programming circuit module according to claim 36, wherein each of the plurality of pin channels is further independently capable of mixed signal testing.

38. The testing and/or programming circuit module according to claim 37, wherein each of the plurality of pin channels is further independently capable of design verification and characterization.

39. The testing and/or programming circuit module according to claim 29, wherein said control circuit and said plurality of configurable channels are implemented as a single integrated circuit.

40. The testing and/or programming circuit module according to claim 39, wherein said integrated circuit further includes a test pattern generating circuit, a timing measuring circuit, and a formation circuit.

41. The testing and/or programming circuit module according to claim 40, wherein said integrated circuit further includes a failure analysis circuit.

42. The testing and/or programming circuit module according to claim 39, wherein said integrated circuit further includes said memory.

43. The testing and/or programming circuit module according to claim 29, wherein said at least one integrated circuit includes at least one memory or programmable device, said control circuit operative to generate a representation of defective locations in the at least one memory or programmable device.

44. The system according to claim 43, said control circuit further operative in programming said at least one memory or programmable device based on said representation of defective locations in the at least one memory or programmable device.

45. A system for testing and/or programming at least one integrated circuit, comprising:
a controller that (i) generates test patterns and/or control signals for testing the at least one integrated circuit and/or (ii) stores program code and/or control signals for programming the at least one integrated circuit; and
a plurality of circuit modules that are coupled to said controller and each include a plurality of pin channels that are capable of being coupled to a respective node of said at least one integrated circuit, each circuit module including circuitry to provide at least DC, AC, and functional testing operations and/or programming based on the test patterns, control signals, and/or program code generated and/or stored by said controller.

46. The system according to claim 45, wherein said controller is a personal computer.

47. The system according to claim 45, wherein said controller, said plurality of circuit modules, and said at least one integrated circuit are mounted on a printed circuit board.

48. A method for testing a plurality of integrated circuits, comprising:
conducting a burn-in operation on said plurality of integrated circuits located in a burn-in oven; and
performing AC, DC, and functional testing on said plurality of integrated circuits while conducting the burn-in operation.

49. The method according to claim 48, further comprising programming said plurality of integrated circuits while located in the burn-in oven.

50. A method for programming a plurality of integrated circuits, comprising:
conducting a burn-in operation on said plurality of integrated circuits located in a burn-in oven; and
programming said plurality of integrated circuits while located in the burn-in oven.

51. The method according to claim 50, wherein said programming is performed while conducting the burn-in operation.

52. The method according to claim 50, wherein said programming is performed after the burn-in operation.

53. A system for testing and/or programming at least one integrated circuit, comprising:
a controller that (i) generates test patterns and/or control signals for testing the at least one integrated circuit and/or (ii) stores program code and/or control signals for programming the at least one integrated circuit; and
a plurality of circuit modules that are coupled to said controller and each include a plurality of pin channels that are capable of being coupled to a respective node of said at least one integrated circuit, each circuit module testing and/or programming said at least one integrated circuit at the speed specified by said at least one integrated circuit, the testing and/or programming based on the test patterns, control signals, and/or program code generated and/or stored by said controller.

54. The system according to claim 1, wherein said third bus operates at a speed specified by said at least one integrated circuit.

55. The method according to claim 22, wherein the testing and/or programming signals are transmitted to said at least one integrated circuit at a speed specified by said at least one integrated circuit.

56. The system according to claim 26, wherein the testing and/or programming signals are transmitted to said at least one integrated circuit at a speed specified by said at least one integrated circuit.

57. The system according to claim 29, wherein the testing and/or programming signals are transmitted to the respective nodes at a speed specified by said at least one integrated circuit.
